(19) United States
(12) Patent Application Publication
(10) Pub. No.: US 2025/0105219 A1
(43) Pub. Date: Mar. 27, 2025

(54) Electroluminescent Display Device and Method of Manufacturing the Same

(71) Applicant: LG Display Co., Ltd., Seoul (KR)

(72) Inventor: Choong-Hyo Kim, Pajui-si (KR)

(21) Appl. No.: 18/884,688

(22) Filed: Sep. 13, 2024

(30) Foreign Application Priority Data
Sep. 22, 2023 (KR) 10-2023-0127140

(51) Int. Cl. H01L 25/075; H01L 33/38

(52) U.S. Cl. CPC H01L 25/0753; H10H 20/831

(57) ABSTRACT

An electroluminescent display device includes a substrate including an emission area and a contact area; a power line over the substrate; a light-emitting diode in the emission area and including a first electrode, a light-emitting layer, and a second electrode; at least one structure in the contact rea; an auxiliary electrode in the contact area, connected to the power line and the second electrode, and having an inclined surface over the structure; and an insulation layer between the auxiliary electrode and the light-emitting diode and having a contact hole exposing the auxiliary electrode, wherein an undercut structure is on at least one side of the contact hole, and the light-emitting layer and the second electrode are cut off by the undercut structure and are in contact with the inclined surface of the auxiliary electrode under the undercut structure.

### CROSS-REFERENCE TO RELATED APPLICATION

The present application claims priority to Republic of Korea Patent Application No. 10-2023-0127140 filed on Sep. 22, 2023, which is hereby incorporated by reference in its entirety.

### BACKGROUND

### Field of the Disclosure

The present disclosure relates to a display device, and more particularly, to an electroluminescent display device including a light-emitting diode and a method of manufacturing the same.

### Discussion of the Background Art

As one of the flat panel display devices, an electroluminescent display device has wide viewing angles, as compared with a liquid crystal display device, because it is self-luminous. The electroluminescent display device also has advantages of a thin thickness, light weight and low power consumption because a backlight unit is not necessary.

In addition, the electroluminescent display device is driven by low voltages of direct current (DC) and has a fast response time. Further, the electroluminescent display device is strong against the external impacts and is used in a wide range of temperatures because its components are solids. Also, the electroluminescent display device can be manufactured at low costs.

The electroluminescent display device can include a plurality of pixels, each of which has a plurality sub-pixels emitting light of different colors, and can display various color images by allowing the plurality of sub-pixels to selectively emit light. Each sub-pixel includes a light-emitting diode, and the light-emitting diode includes a first electrode, a light-emitting layer, and a second electrode.

Here, the first electrode is provided for each sub-pixel, and the second electrode is provided commonly for all sub-pixels. That is, the second electrode is provided to correspond to an entire display area, so that the second electrode is formed in a relatively large area.

The resistance of the second electrode increases depending on the position, causing a difference in resistance. Accordingly, there is a problem that the luminance of the electroluminescent display device is non-uniform due to difference in resistance.

### SUMMARY

Accordingly, the present disclosure is to provide an electroluminescent display device and a method of manufacturing the same that substantially obviates one or more of the limitations and disadvantages described above and associated with the background art.

More specifically, an object of the present disclosure is to provide an electroluminescent display device having uniform luminance and a method of manufacturing the same.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other embodiments of the present disclosure, as embodied and broadly described herein, an electroluminescent display device comprises: a substrate including an emission area and a contact area; a power line over the substrate; a light-emitting diode in the emission area, the light-emitting diode including a first electrode, a light-emitting layer on the first electrode, and a second electrode on the light-emitting layer; at least one structure in the contact area; an auxiliary electrode in the contact area and connected to the power line and the second electrode, the auxiliary electrode having an inclined surface over the at least one structure; and an insulation layer between the auxiliary electrode and the light-emitting diode, the insulation layer having a contact hole exposing the auxiliary electrode, wherein a portion of the insulation layer extends past the inclined surface of the auxiliary electrode and an undercut structure is between the inclined surface of the auxiliary electrode and a bottom surface of the portion of the insulation layer that is exposed on at least one side of the contact hole, and wherein the light-emitting layer and the second electrode are respectively disconnected from another light-emitting layer and another second electrode by the undercut structure such that an end of the light-emitting layer and an end of the second electrode are in contact with the inclined surface of the auxiliary electrode at a location that is under the undercut structure.

In another embodiment, a method of manufacturing an electroluminescent display comprises: forming a power line and at least one structure over a substrate; forming an auxiliary electrode over the substrate, the auxiliary electrode connected to the power line and having an inclined surface over the at least one structure; forming a first insulation layer having a first contact hole and a second insulation layer having a second contact hole over the auxiliary electrode such that a portion of the first insulation layer extends past the inclined surface of the auxiliary electrode and an undercut structure is formed between the inclined surface of the auxiliary electrode and a bottom surface of the portion of the first insulation layer that is exposed on at least one side of the first contact hole; and forming a light-emitting diode over the second insulation layer, the light-emitting diode including a first electrode, a light-emitting layer on the first electrode, and a second electrode on the first electrode, wherein the light-emitting layer and the second electrode are respectively disconnected from another light-emitting layer and another second electrode by the undercut structure such that the light-emitting layer and the second electrode are in contact with the inclined surface of the auxiliary electrode at a location that is under the undercut structure.

In one embodiment, a display device comprises: a substrate including an emission area and a contact area; a power line on the substrate, the power line supplying a voltage; a transistor on the substrate; a light emitting element in the emission area and connected to the transistor, the light emitting element including a first electrode, a light-emitting layer on the first electrode, and a second electrode on the light-emitting layer; and an auxiliary electrode in the contact area that is connected to the power line and the second electrode, the auxiliary electrode having a flat surface and an inclined surface that extends from the flat surface with respect to the substrate, wherein an end of the second electrode contacts the inclined surface of the auxiliary electrode in the contact area.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is an example of an equivalent circuit diagram of one sub-pixel of an electroluminescent display device according to an embodiment of the present disclosure;

FIG. 2 is a schematic plan view of an electroluminescent display device according to an embodiment of the present disclosure;

FIG. 3 is a cross-sectional view of the line I-I′ of FIG. 2 according to an embodiment of the present disclosure.

FIG. 4 is a schematic plan view of another electroluminescent display device according to an embodiment of the present disclosure;

FIG. 5 is a cross-sectional view of the line II-II′ of FIG. 4 according to an embodiment of the present disclosure;

FIG. 6 is a schematic plan view of a contact area of an electroluminescent display device according to a first embodiment of the present disclosure;

FIG. 7 is a cross-sectional view corresponding to the line IIIA-IIIA′ and the line IIIB-IIIB′ of FIG. 6 according to an embodiment of the present disclosure;

FIGS. 8A to 8J are schematic cross-sectional views of a contact area in steps of manufacturing an electroluminescent display device according to the first embodiment of the present disclosure;

FIG. 9 is a schematic plan view of a contact area of an electroluminescent display device according to a second embodiment of the present disclosure;

FIG. 10 is a cross-sectional view corresponding to the line IV-IV′ of FIG. 9 according to an embodiment of the present disclosure;

FIG. 11 is a schematic plan view of a contact area of an electroluminescent display device according to a third embodiment of the present disclosure;

FIG. 12 is a cross-sectional view corresponding to the line VA-VA′ and the line VB-VB′ of FIG. 11 according to an embodiment of the present disclosure;

FIG. 13 is a schematic plan view of a contact area of an electroluminescent display device according to a fourth embodiment of the present disclosure;

FIG. 14 is a cross-sectional view corresponding to the line VIA-VIA′ and the line VIB-VIB′ of FIG. 13 according to an embodiment of the present disclosure;

FIGS. 15A to 15J are schematic cross-sectional views of a contact area in steps of manufacturing an electroluminescent display device according to the fourth embodiment of the present disclosure;

FIG. 16 is a schematic plan view of a contact area of an electroluminescent display device according to a fifth embodiment of the present disclosure;

FIG. 17 is a cross-sectional view corresponding to the line VIIA-VIIA′ and the line VIIB-VIIB′ of FIG. 16 according to an embodiment of the present disclosure;

FIG. 18 is a schematic plan view of a contact area of an electroluminescent display device according to a sixth embodiment of the present disclosure;

FIG. 19 is a cross-sectional view corresponding to the line VIIIA-VIIIA′ and the line VIIIB-VIIIB′ of FIG. 18 according to an embodiment of the present disclosure;

FIGS. 20A to 20K are schematic cross-sectional views of a contact area in steps of manufacturing an electroluminescent display device according to the sixth embodiment of the present disclosure;

FIG. 21 is a schematic cross-sectional view of a contact area of an electroluminescent display device according to a seventh embodiment of the present disclosure; and

FIG. 22 is a schematic cross-sectional view of a contact area of an electroluminescent display device according to an eighth embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

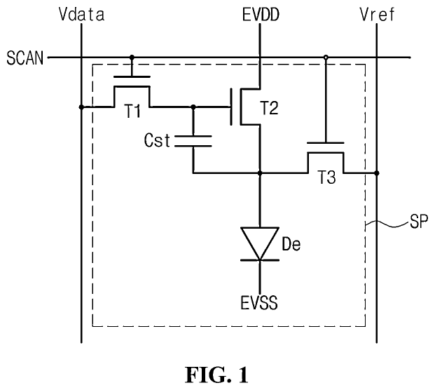

An electroluminescent display device according to embodiments of the present disclosure includes a plurality of pixels arranged in the form of a matrix (or any other form) in a display area, and each pixel includes a plurality of sub-pixels. Each sub-pixel has the same or substantially the same configuration as other sub-pixels. Now, one example of the configuration of such sub-pixel of the electroluminescent display device will be described with reference to FIG. 1, but other configurations are possible.

FIG. 1 is an example of an equivalent circuit diagram of one sub-pixel SP of an electroluminescent display device according to an embodiment of the present disclosure.

In FIG. 1, the sub-pixel SP of the electroluminescent display device according to the embodiment of the present disclosure can include first transistor T1, second transistor T2, and third transistor T3, a storage capacitor Cst, and a light-emitting diode De. The first, second, and third transistors T1, T2, and T3 can be a switching transistor T1, a driving transistor T2, and a sensing transistor T3, respectively. The switching transistor T1, the driving transistor T2, and the sensing transistor T3 can be n-type transistors. However, the present disclosure is not limited thereto. Alternatively, the switching transistor T1, the driving transistor T2, and the sensing transistor T3 can be p-type transistors or other types of transistors.

A gate line supplying a scan signal (or gate signal) SCAN and a data line supplying a data signal Vdata can cross each other, and the switching transistor T1 can be disposed at a crossing point of the gate line and the data line. A gate of the switching transistor T1 can be connected to the gate line to receive the gate signal SCAN, and a drain of the switching transistor T1 can be connected to the data line to receive the data signal Vdata.

In addition, a gate of the driving transistor T2 can be connected to a source of the switching transistor T1 and a first capacitor electrode of the storage capacitor Cst. A drain of the driving transistor T2 can be connected to a high potential line supplying a high potential voltage EVDD, and a source of the driving transistor T2 can be connected to an anode of the light-emitting diode De, a second capacitor electrode of the storage capacitor Cst, and a source of the sensing transistor T3.

A gate of the sensing transistor T3 can be connected to the gate line, and a drain of the sensing transistor T3 can be connected to a reference line supplying a reference voltage Vref. Alternatively, the gate of the sensing transistor T3 can be connected to a separate sensing line.

Here, the source and drain locations of each of the transistors T1, T2, and T3 are not limited thereto, and the locations can be interchanged or varied.

Meanwhile, a cathode of the light-emitting diode De can be connected to a low potential line supplying a low potential voltage EVSS. Alternatively, the cathode of the light-emitting diode De can be connected to a ground voltage. As a variation, instead of the light-emitting diode De, another type of light-emitting element can be used.

During an emission period of one frame, the switching transistor T1 can be switched according to the gate signal SCAN transmitted through the gate line to thereby provide the gate of the driving transistor T2 with the data signal Vdata transmitted through the data line. The driving transistor T2 can be switched according to the data signal Vdata to thereby control a current of the light-emitting diode De. In this case, the storage capacitor Cst can maintain charges corresponding to the data signal Vdata for one frame. Accordingly, even if the switching transistor T1 is turned off, the storage capacitor Cst can allow the amount of the current flowing through the light-emitting diode De to be constant and the gray level shown by the light-emitting diode De to be maintained until a next frame.

In addition, one frame can further include a sensing period. During the sensing period, the sensing transistor T3 can be switched according to the gate signal SCAN transmitted through the gate line to thereby provide the source of the driving transistor T2 with the reference voltage Vref. The sensing transistor T3 can detect the voltage change of the source of the driving transistor T2 through the reference line and can calculate the threshold voltage Vth of the driving transistor T2 by comparing the amount of the voltage change with a determination range. Accordingly, by calculating the threshold voltage Vth in real time and compensating for the image data, it is possible to compensate for the change in the characteristics of the driving transistor T2 and prevent image degradation.

However, the configuration of the sub-pixel of the electroluminescent display device according to the embodiment of the present disclosure is not limited thereto. In some embodiments, the sensing transistor T3 can be omitted. In addition, the number and connection relationship of the transistors, the storage capacitor and/or the light-emitting diode can vary.

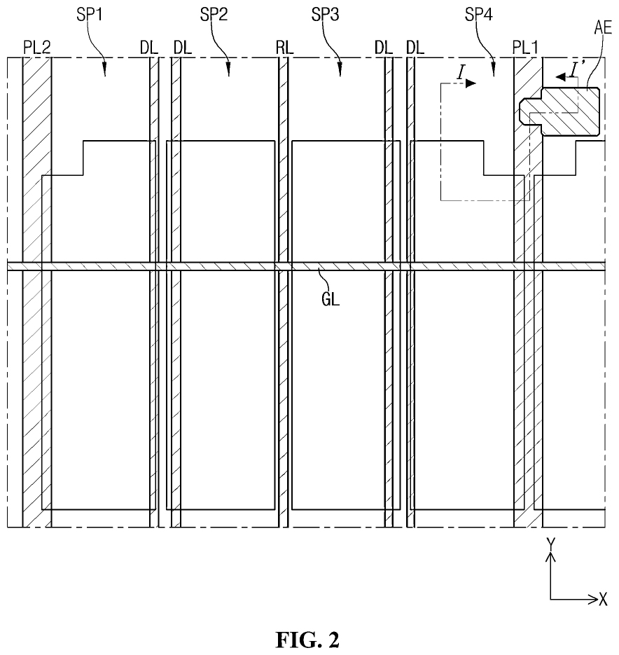

FIG. 2 is a schematic plan view of an electroluminescent display device according to an embodiment of the present disclosure and shows one sub-pixel. The electroluminescent display device according to an embodiment of the present disclosure can be a top emission type display device.

As shown in FIG. 2, in an electroluminescent display device according to an embodiment of the present disclosure, a gate line GL can extend in a first direction, which is an X direction. A plurality of data lines DL, a first power line PL1, a second power line PL2, and a reference line RL can extend in a second direction, which is a Y direction. The gate line GL can cross the data lines DL, the first power line PL1, the second power line PL2, and the reference line RL to thereby define a plurality of sub-pixels SP1, SP2, SP3, and SP4. Here, the first power line PL1 can be the low potential line supplying the low potential voltage EVSS of FIG. 1, and the second power line PL2 can be the high potential line supplying the high potential voltage EVDD of FIG. 1.

The gate line GL can pass through each sub-pixel SP1, SP2, SP3, and SP4. However, embodiments of the present disclosure are not limited thereto. Alternatively, the gate line GL can be disposed at a top or bottom portion of each sub-pixel SP1, SP2, SP3, and SP4.

One reference line RL can be disposed between the first and second power lines PL1 and PL2, and a first pair of data lines DL can be disposed between the first power line PL1 and the reference line RL and a second pair of data lines DL can be disposed between the second power line PL2 and the reference line RL. Two data lines DL can be disposed adjacent to each other substantially at the center between the reference line RL and the first power line PL1 or second power line PL2.

Each sub-pixel SP1, SP2, SP3, and SP4 can have a substantially rectangular shape. However, embodiments of the present disclosure are not limited thereto, and each sub-pixel SP1, SP2, SP3, and SP4 can have other shapes.

As described above, one pixel can include the plurality of sub-pixels SP1, SP2, SP3, and SP4. For example, one pixel can include four sub-pixels, that is, first, second, third, and fourth sub-pixels SP1, SP2, SP3, and SP4. The first, second, third, and fourth sub-pixels SP1, SP2, SP3, and SP4 can be sequentially arranged along the first direction.

Here, the first sub-pixel SP1 can be a red sub-pixel, the second sub-pixel SP2 can be a green sub-pixel, the third sub-pixel SP3 can be a blue sub-pixel, and the fourth sub-pixel SP4 can be a white sub-pixel. However, embodiments of the present disclosure are not limited thereto. In other embodiments, the number of sub-pixels included in one pixel and/or the arrangement order of the red, green, blue, and white sub-pixels can be changed.

The first, second, third, and fourth sub-pixels SP1, SP2, SP3, and SP4 can have substantially the same area. However, embodiments of the present disclosure are not limited thereto. In other embodiments, the first, second, third, and fourth sub-pixels SP1, SP2, SP3, and SP4 can have different areas from each other.

Here, one power line PL1 or PL2, two data lines DL, or one reference line RL can be disposed substantially between adjacent sub-pixels SP1, SP2, SP3, and SP4. For example, two data lines DL can be disposed between the first and second sub-pixels SP1 and SP2 and between the third and fourth sub-pixels SP3 and SP4, one reference line RL can be disposed between the second and third sub-pixels SP2 and SP3, and one first power line PL1 can be disposed between the fourth sub-pixel SP4 and a first sub-pixel SP1 of a next pixel. In addition, two pixels adjacent to each other in the first direction can be symmetrical with respect to the first power line PL1 or second power line PL2. However, embodiments of the present disclosure are not limited thereto.

In each sub-pixel SP1, SP2, SP3, and SP4, the light-emitting diode De, the first, second, and third transistors T1, T2, and T3, and the storage capacitor Cst of FIG. 1 can be provided.

The light-emitting diode De can include a first electrode, a light-emitting layer, and a second electrode. The first electrode can be provided at each sub-pixel SP1, SP2, SP3, and SP4. The second electrode can be commonly provided over all sub-pixels SP1, SP2, SP3, and SP4.

Meanwhile, an auxiliary electrode AE can be provided to partially overlap the first power line PL1. The auxiliary electrode AE can be provided for each pixel and can be disposed to correspond to the fourth sub-pixel SP4.

The auxiliary electrode AE can be connected to the first power line PL1, and the second electrode of the light-emitting diode De can be connected to the auxiliary electrode AE. Accordingly, the second electrode of the light-emitting diode De can be electrically connected to the first power line PL1 through the auxiliary electrode AE. Therefore, the resistance of the second electrode can be reduced, and the luminance of the electroluminescent display device can be uniform.

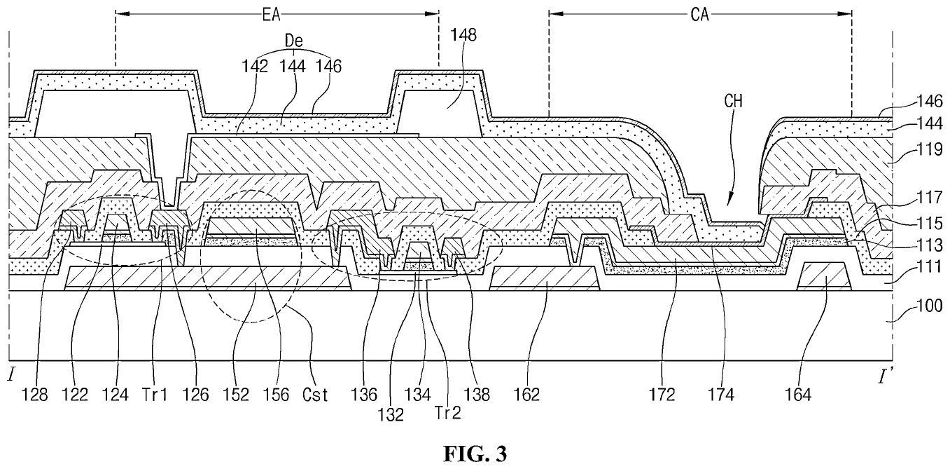

A cross-sectional configuration of the electroluminescent display device according to the embodiment of the present disclosure will be described with reference to FIG. 3.

FIG. 3 is a cross-sectional view of the line I-I′ of FIG. 2 and shows a cross-section of one sub-pixel according to one embodiment.

In FIG. 3, a sub-pixel of the electroluminescent display device according to the embodiment of the present disclosure can include an emission area EA and a contact area CA provided on a substrate 100. Thus, the substrate 100 includes the emission area EA and the contact area CA. A light-emitting diode De can be provided in the emission area EA, and an auxiliary electrode 172 and 174 can be provided in the contact area CA. The light-emitting diode De can include a first electrode 142, a light-emitting layer 144, and a second electrode 146, and the second electrode 146 can be electrically connected to a power line 162 through the auxiliary electrode 172 and 174.

Specifically, a light-blocking layer 152, the power line 162, and a dummy pattern 164 can be provided on the substrate 100. The substrate 100 can be formed of a transparent insulating material and for example, can be a glass substrate or a plastic substrate. Polyimide can be used for the plastic substrate, but embodiments are not limited thereto.

The light-blocking layer 152 can be disposed in the emission area EA, and a part of the light-blocking layer 152 can function as a first capacitor electrode. The dummy pattern 164 can be disposed in the contact area CA. The power line 162 can be disposed substantially between the emission area EA and the contact area CA. Here, the power line 162 can correspond to the first power line PL1 of FIG. 2 and can be a low potential power line providing a low potential voltage.

The dummy pattern 164 can be provided on the same layer and of the same material as the light-blocking layer 152 and the power line 162. The dummy pattern 164 can have an inclined side surface. That is, the side surface of the dummy pattern 164 can have an inclination with a predetermined angle with respect to the substrate 100.

The light-blocking layer 152, the power line 162, and the dummy pattern 164 can be formed of a conductive material such as metal. The light-blocking layer 152, the power line 162, and the dummy pattern 164 can be formed of one or more of: aluminum (Al), copper (Cu), molybdenum (Mo), titanium (Ti), chromium (Cr), nickel (Ni), tungsten (W), and an alloy thereof. For example, the light-blocking layer 152, the power line 162, and the dummy pattern 164 can have a double-layered structure including a lower layer of a molybdenum-titanium alloy (MoTi) and an upper layer of copper (Cu), and the upper layer can have a thicker thickness than the lower layer. However, embodiments of the present disclosure are not limited thereto. In other embodiments, the light-blocking layer 152, the power line 162, and the dummy pattern 164 can have a single-layered structure or a triple-layered structure.

A buffer layer 111 of an insulating material can be provided on the light-blocking layer 152, the power line 162, and the dummy pattern 164. The buffer layer 111 can be disposed over substantially an entire surface of the substrate 100. The buffer layer 111 can be formed of an inorganic insulating material, such as silicon oxide (SiO₂) or silicon nitride (SiNₓ), and can be formed as a single layer or multiple layers.

A first semiconductor layer 122 and a second semiconductor layer 132 can be patterned and provided on the buffer layer 111. The first semiconductor layer 122 and the second semiconductor layer 132 can be disposed to correspond to the emission area EA.

The first semiconductor layer 122 can overlap the light-blocking layer 152, and the second semiconductor layer 132 can spaced apart from the light-blocking layer 152. The light-blocking layer 152 can block light incident on the first semiconductor layer 122, and reduce or prevent the first semiconductor layer 122 from deteriorating due to the light. However, embodiments of the present disclosure are not limited thereto. In other embodiments, both the first semiconductor layer 122 and the second semiconductor layer 132 can overlap the light-blocking layer 152.

The first semiconductor layer 122 and the second semiconductor layer 132 can be formed of an oxide semiconductor material.

Alternatively, the first semiconductor layer 122 and the second semiconductor layer 132 can be formed of polycrystalline silicon. In this case, both end portions of each of the first semiconductor layer 122 and the second semiconductor layer 132 can be doped with impurities.

A gate insulation layer 113 of an insulating material can be disposed on the buffer layer 111 provided with the first semiconductor layer 122 and the second semiconductor layer 132 thereon, and a first gate electrode 124, a second gate electrode 134, a second capacitor electrode 156, and a first auxiliary electrode 172 can be disposed on the gate insulation layer 113.

The gate insulation layer 113 can be patterned to have substantially the same shape as each of the first gate electrode 124, the second gate electrode 134, the second capacitor electrode 156, and the first auxiliary electrode 172. However, embodiments of the present disclosure are not limited thereto. In other embodiments, the gate insulation layer 113 can be disposed over substantially the entire surface of the substrate 100.

The gate insulation layer 113 can be formed of an inorganic insulating material, such as silicon oxide (SiO₂) or silicon nitride (SiNₓ). When the first semiconductor layer 122 and the second semiconductor layer 132 are made of an oxide semiconductor material, the gate insulation layer 113 can be formed of silicon oxide (SiO₂).

Alternatively, when the first semiconductor layer 122 and the second semiconductor layer 132 are made of polycrystalline silicon, the gate insulation layer 113 can be formed of silicon oxide (SiO₂) or silicon nitride (SiNₓ).

The first gate electrode 124, the second gate electrode 134, and the second capacitor electrode 156 can be disposed substantially in the emission area EA, and the first auxiliary electrode 172 can be disposed in the contact area CA.

In this case, the first gate electrode 124 can be disposed to correspond to a center of the first semiconductor layer 122, and the second gate electrode 134 can be disposed to correspond to a center of the second semiconductor layer 132. Accordingly, the first gate electrode 124 can overlap the light-blocking layer 152, and the second gate electrode 134 can be spaced part from the light-blocking layer 152. Alternatively, when the second semiconductor layer 132 overlaps the light-blocking layer 152, the second gate electrode 134 can overlap the light-blocking layer 152.

In addition, the second capacitor electrode 156 can overlap the light-blocking layer 152. The light-blocking layer 152 and the second capacitor electrode 156 overlapping each other can constitute a storage capacitor Cst with the buffer layer 111 and the gate insulation layer 113 interposed therebetween as a dielectric.

Meanwhile, the first auxiliary electrode 172 can overlap the power line 162 and be in contact with the power line 162 through a contact hole provided in the gate insulation layer 113 and buffer layer 111. Further, the first auxiliary electrode 172 can overlap the dummy pattern 164 and have a flat surface and an inclined surface that extends from the flat surface with respect to the substrate 100. That is, an inclined step surface is due to the inclined side surface of the dummy pattern 164.

The first gate electrode 124, the second gate electrode 134, the second capacitor electrode 156, and the first auxiliary electrode 172 can be formed of a conductive material such as metal. The first gate electrode 124, the second gate electrode 134, the second capacitor electrode 156, and the first auxiliary electrode 172 can be formed of one or more of: aluminum (Al), copper (Cu), molybdenum (Mo), titanium (Ti), chromium (Cr), nickel (Ni), tungsten (W), and an alloy thereof. For example, the first gate electrode 124, the second gate electrode 134, the second capacitor electrode 156, and the first auxiliary electrode 172 can have a double-layered structure, including a lower layer of a molybdenum-titanium alloy (MoTi) and an upper layer of copper (Cu), and the upper layer can be thicker than the lower layer. However, embodiments of the present disclosure are not limited thereto. In other embodiments, the first gate electrode 124, the second gate electrode 134, the second capacitor electrode 156, and the first auxiliary electrode 172 can have a single-layered structure or a triple-layered structure.

A first passivation layer 115 of an insulating material can be provided on the first gate electrode 124, the second gate electrode 134, the second capacitor electrode 156, and the first auxiliary electrode 172. The first passivation layer 115 can be disposed over substantially the entire surface of the substrate 100. The first passivation layer 115 can be an interlayer insulation layer and can be formed of an inorganic insulating material, such as silicon oxide (SiO₂) or silicon nitride (SiNₓ).

The first passivation layer 115 can have a contact hole exposing a portion of the first auxiliary electrode 172 in the contact area CA.

First source and first drain electrodes 126 and 128 and second source and second drain electrodes 136 and 138 can be disposed on the first passivation layer 115. The source and first drain electrodes 126 and 128 and the second source and second drain electrodes 136 and 138 can be formed of a conductive material such as metal. The source and first drain electrodes 126 and 128 and the second source and second drain electrodes 136 and 138 can be formed of one or more of: aluminum (Al), copper (Cu), molybdenum (Mo), titanium (Ti), chromium (Cr), nickel (Ni), tungsten (W), and an alloy thereof. For example, the source and first drain electrodes 126 and 128 and the second source and second drain electrodes 136 and 138 can have a double-layered structure, including a lower layer of a molybdenum-titanium alloy (MoTi) and an upper layer of copper (Cu), and the upper layer can be thicker than the lower layer. However, embodiments of the present disclosure are not limited thereto. In other embodiments, the source and first drain electrodes 126 and 128 and the second source and second drain electrodes 136 and 138 can have a single-layered structure or a triple-layered structure.

The first source electrode 126 and the first drain electrode 128 can be spaced apart from each other with the first gate electrode 124 positioned therebetween and can be in contact with both end portions of the first semiconductor layer 122 through contact holes provided in the first passivation layer 115, respectively. In addition, the second source electrode 136 and the second drain electrode 138 can be spaced apart from each other with the second gate electrode 134 positioned therebetween and can be in contact with the both end portions of the second semiconductor layer 132 through contact holes provided in the first passivation layer 115.

The first semiconductor layer 122, the first gate electrode 124, the first source electrode 126, and the first drain electrode 128 can form a first thin film transistor Tr1. The second semiconductor layer 132, the second gate electrode 134, the second source electrode 136, and the second drain electrode 138 can form a second thin film transistor Tr2.

The first and second thin film transistors Tr1 and Tr2 can have a coplanar structure in which the gate electrode 124 and 134 and the source and drain electrodes 126, 128, 136, and 138 can be located at the same side with respect to the semiconductor layer 122 and 132, that is, disposed over the semiconductor layer 122 and 132.

Alternatively, the first and second thin film transistors Tr1 and Tr2 can have an inverted staggered structure in which the gate electrode and the source and drain electrodes can be located at different sides with respect to the semiconductor layer. That is, the gate electrode can be disposed under the semiconductor layer, and the source and drain electrodes can be disposed over the semiconductor layer. In this case, the semiconductor layer can be formed of oxide semiconductor or amorphous silicon.

The first thin film transistor Tr1 can be the driving transistor T2 of FIG. 1, and the second thin film transistor Tr2 can be the sensing transistor T3 of FIG. 1. In addition, at least one thin film transistor having substantially the same structure as the first and second thin film transistors Tr1 and Tr2, for example, the switching transistor T1 of FIG. 1, can be further provided on the substrate 100.

Meanwhile, the first source electrode 126 and the second source electrode 136 can be in contact with the light-blocking layer 152 through contact holes provided in the first passivation layer 115 and the buffer layer 111. Accordingly, the first and second thin film transistors Tr1 and Tr2 can be connected to the storage capacitor Cst.

Next, a second auxiliary electrode 174 can be disposed on the first passivation layer 115 in the contact area CA. The second auxiliary electrode 174 can be in contact with the first auxiliary electrode 172 through a contact hole provided in the first passivation layer 115. The second auxiliary electrode 174 can have an inclined surface that extends from a substantially flat surface of the second auxiliary electrode 174. That is, the auxiliary electrode 174 has an inclined step surface due to the inclined side surface of the dummy pattern 164. A thickness of the second auxiliary electrode 174 can be smaller than a thickness of the first auxiliary electrode 172, and a width of the second auxiliary electrode 174 can be narrower than a width of the first auxiliary electrode 172. The second auxiliary electrode 174 can overlap the dummy pattern 164.

The second auxiliary electrode 174 can be formed of a conductive material such as metal. For example, the second auxiliary electrode 174 can be formed of one or more of: molybdenum (Mo), titanium (Ti), chromium (Cr), nickel (Ni), tungsten (W), and an alloy thereof. Alternatively, the second auxiliary electrode 174 can be formed of a transparent conductive material. For example, the second auxiliary electrode 174 can be formed of indium tin oxide (ITO) or indium zinc oxide (IZO).

Here, the first and second auxiliary electrodes 172 and 174 can correspond to the auxiliary electrode AE of FIG. 2. In one embodiment, the second auxiliary electrode 174 can be omitted.

A second passivation layer 117 of an insulating material can be provided on the first source and first drain electrodes 126 and 128, the second source and second drain electrodes 136 and 138, and the second auxiliary electrode 174. The second passivation layer 117 can be disposed over substantially the entire surface of the substrate 100. The second passivation layer 117 can be a protection layer. The second passivation layer 117 can be formed of an inorganic insulating material, such as silicon oxide (SiO₂) or silicon nitride (SiNₓ). A thickness of the second passivation layer 117 can be thicker than a thickness of the first passivation layer 115.

The second passivation layer 117 can have a contact hole CH exposing the second auxiliary electrode 174 in the contact area CA. An undercut structure where a bottom surface of the second passivation layer 117 is exposed can be provided on at least one side of the contact hole CH. That is, a portion of the second passivation layer 117 extends past the inclined surface of the second auxiliary electrode 174 to create the undercut structure.

An overcoat layer 119 of an insulating material can be provided on the second passivation layer 117. The overcoat layer 119 can be disposed over substantially the entire surface of the substrate 100. The overcoat layer 119 and the second passivation layer 117 can have a contact hole exposing the first source electrode 126 in the emission area EA. In addition, the overcoat layer 119 can have a contact hole exposing the second auxiliary electrode 174 in the contact area CA. In this case, the overcoat layer 119 can cover the second passivation layer 117 at the side provided with the undercut structure and can expose the second passivation layer 117 at a side provided without the undercut structure.

The overcoat layer 119 can be a planarization layer. The overcoat layer 119 can be formed of an organic insulating material such as photosensitive acrylic polymer (photo acryl). The overcoat layer 119 can eliminate a step difference due to the layers thereunder and can have a substantially flat top surface. However, embodiments of the present disclosure are not limited thereto.

The first electrode 142 can be disposed on the overcoat layer 119 in the emission area EA and can be formed of a conductive material having relatively high work function. The first electrode 142 can be in contact with the first source electrode 126 through the contact hole provided in the overcoat layer 119 and the second passivation layer 117.

For example, the first electrode 142 can include a transparent conductive material such as indium tin oxide (ITO) or indium zinc oxide (IZO) or include titanium (Ti). However, embodiments of the present disclosure are not limited thereto.

Meanwhile, as described above, the electroluminescent display device according to the embodiment of the present disclosure can be a top emission type display device, in which light from the light-emitting layer 144 is output toward a direction opposite the substrate 100, that is, output to the outside through the second electrode 146. In this case, the first electrode 142 can have a multi-layered structure including a material with relatively high reflectance. For example, the first electrode 142 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank 148 of an organic insulating material can be disposed on the first electrode 142. The bank 148 can overlap edges of the first electrode 142 and cover the edges of the first electrode 142. The bank 148 can expose a central portion of the first electrode 142.

The bank 148 may not be provided in the contact area CA.

Next, the light-emitting layer 144 can be provided on the first electrode 142 exposed by the bank 148. The light-emitting layer 144 can be disposed over substantially the entire surface of the substrate 100. Accordingly, in the emission area EA, the light-emitting layer 144 can be in contact with the first electrode 142 and also in contact with side and top surfaces of the bank 148. Additionally, the light-emitting layer 144 extends from the emission area EA to the contact area CA. In the contact area CA, the light-emitting layer 144 can be in contact with top and side surfaces of the overcoat layer 119 and can also be in contact with exposed top and side surfaces of the second passivation layer 117, and a top surface of the second auxiliary electrode 174. In the contact area CA, the light-emitting layer 144 can be separated by the undercut structure from the portion of the light-emitting layer 144 in the emission area EA.

The light-emitting layer 144 can emit white light and can include at least one hole auxiliary layer, at least one light-emitting material layer, and at least one electron auxiliary layer constituting one light-emitting unit. The hole auxiliary layer can include at least one of a hole injection layer (HIL) and a hole transport layer (HTL). The electron auxiliary layer can include at least one of an electron injection layer (EIL) and an electron transport layer (ETL).

The light-emitting layer 144 can have a stack structure in which two or more light-emitting units emitting light of different colors are stacked, and a charge generation layer (CGL) can be provided between two light-emitting units.

The second electrode 146 of a conductive material with relatively low work function can be provided on the light-emitting layer 144. The second electrode 146 can be disposed over substantially the entire surface of the substrate 100.

The second electrode 146 can be formed of aluminum (Al), magnesium (Mg), silver (Ag), or an alloy thereof. In this case, the second electrode 146 can have a relatively thin thickness such that light from the light-emitting layer 144 can be transmitted therethrough. For example, the second electrode 146 can have a thickness of 5 nm to 10 nm, but embodiments of the present disclosure are not limited thereto.

Alternatively, the second electrode 146 can be formed of a transparent conductive material such as indium gallium oxide (IGO) or IZO.

The second electrode 146 can be in contact with a top surface of the light-emitting layer 144. In the contact area CA, the second electrode 146 can be separated from the portion of the second electrode 146 that extends from the emission area EA by the undercut structure and be in contact with the second auxiliary electrode 174 under the undercut structure. This will be described in detail later.

The first electrode 142, the light-emitting layer 144, and the second electrode 146 of the emission area EA can constitute the light-emitting diode De. Here, the first electrode 142 can serve as an anode, and the second electrode 146 can serve as a cathode. However, embodiments of the present disclosure are not limited thereto. In other embodiments, the first electrode 142 can serve as a cathode, and the second electrode 146 can serve as an anode.

Although not shown in the figure, a capping layer can be formed on the second electrode 146 over substantially the entire surface of the substrate 100. The capping layer can be formed of an insulating material having a relatively high refractive index. The wavelength of light traveling along the capping layer can be amplified by surface plasma resonance. Thus, the intensity of the peak can be increased, thereby improving the light efficiency in the top-emission type electroluminescent display device. For example, the capping layer can be formed as a single layer of an organic layer or an inorganic layer, or can be formed as organic/inorganic stacked layers.

In addition, although not shown in the figure, an encapsulation layer can be provided on the capping layer. The encapsulation layer can protect the light-emitting diode De from external moisture or oxygen. The encapsulation layer can include at least one inorganic layer and at least one organic layer.

As described above, the electroluminescent display device according to the embodiment of the present disclosure can be the top emission type display device, in which light from the light-emitting layer 144 of the light-emitting diode De is output toward a direction opposite the substrate 100, that is, output to the outside through the second electrode 146. The top emission type display device can have a wider emission area than a bottom emission type display device of the same size, which may improve luminance and reduce power consumption.

By the way, to transmit light, the second electrode 146 should be formed of a metal material to have a thin thickness or formed of a transparent conductive material. According to this, the resistance of the second electrode 146 can increase, and there is a difference of the resistance depending on locations. Therefore, in the embodiment of the present disclosure, to reduce the resistance of the second electrode 146, the second electrode 146 can be electrically connected to the power line 162 through the auxiliary electrode 172 and 174.

In this case, the light-emitting layer 144 can be disposed between the second electrode 146 and the auxiliary electrode 172 and 174. Since the light-emitting layer 144 has insulating properties and acts as a resistor, contact properties between the second electrode 146 and the auxiliary electrode 172 and 174 can be deteriorated.

Accordingly, in the embodiment of the present disclosure, by forming the undercut structure between the second electrode 146 and the auxiliary electrode 172 and 174, more particularly, between the light-emitting layer 144 and the auxiliary electrode 172 and 174, the second electrode 146 can be in direct contact with the auxiliary electrode 172 and 174.

In addition, a structure such as the dummy pattern 164 may be provided under the auxiliary electrode 172 and 174, so that the auxiliary electrode 172 and 174 can have the inclined surface and the second electrode 146 can be in contact with the inclined surface, thereby facilitating contact between the second electrode 146 and the auxiliary electrode 172 and 174. In one embodiment, an end of the second electrode 146 contacts the inclined surface of the auxiliary electrode 174 without the second electrode 146 contacting the flat surface of the auxiliary electrode 174 as shown in FIG. 3. As shown in FIG. 3, the light-emitting layer 144 contacts the flat surface and the inclined surface of the auxiliary electrode 174.

Therefore, the contact properties between the second electrode 146 and the auxiliary electrode 172 and 174 can be increased, and a difference in resistance of the second electrode 146 can be prevented, so that the luminance of the electroluminescent display device can be made uniform.

Meanwhile, an electroluminescent display device according to the embodiment of the present disclosure can further include a transparent area.

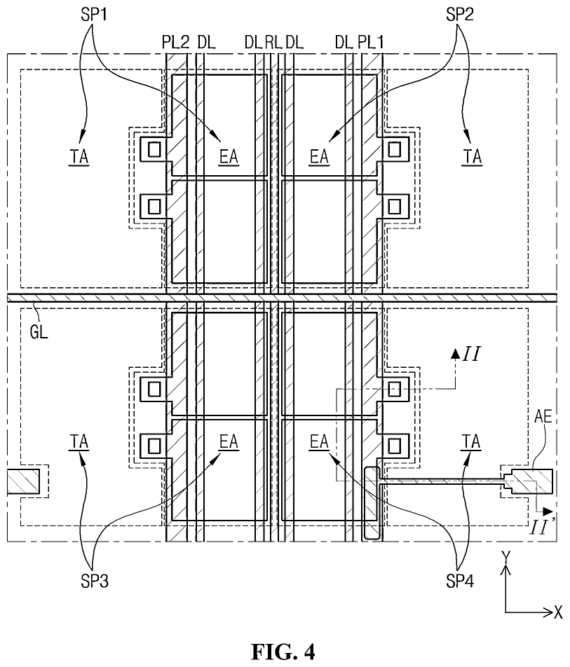

FIG. 4 is a schematic plan view of another electroluminescent display device according to an embodiment of the present disclosure and shows one sub-pixel. Another electroluminescent display device according to an embodiment of the present disclosure can be a transparent display device including an emission area and a transparent area.

As shown in FIG. 4, in another electroluminescent display device according to an embodiment of the present disclosure, a gate line GL can extend in a first direction, which is an X direction. A plurality of data lines DL, a first power line PL1, a second power line PL2, and a reference line RL can extend in a second direction, which is a Y direction. The gate line GL can cross the data lines DL, the first power line PL1, the second power line PL2, and the reference line RL to thereby define a plurality of sub-pixels SP1, SP2, SP3, and SP4. Here, the first power line PL1 can be the low potential line supplying the low potential voltage EVSS of FIG. 1, and the second power line PL2 can be the high potential line supplying the high potential voltage EVDD of FIG. 1.

The gate line GL can be disposed between adjacent sub-pixels SP1, SP2, SP3, and SP4 along the second direction. However, embodiments of the present disclosure are not limited thereto.

One reference line RL can be disposed between the first and second power lines PL1 and PL2, and two data lines DL can be disposed between the first power line PL1 and the reference line RL and between the second power line PL2 and the reference line RL.

Each sub-pixel SP1, SP2, SP3, and SP4 can have a substantially rectangular shape. However, embodiments of the present disclosure are not limited thereto, and each sub-pixel SP1, SP2, SP3, and SP4 can have other shapes.

As described above, one pixel can include the plurality of sub-pixels SP1, SP2, SP3, and SP4. For example, one pixel can include four sub-pixels, that is, first, second, third, and fourth sub-pixels SP1, SP2, SP3, and SP4. The first, second, third, and fourth sub-pixels SP1, SP2, SP3, and SP4 can be arranged in a pentile shape. That is, the first and second sub-pixels SP1 and SP2 can be disposed adjacent to each other in the first direction, the third and fourth sub-pixels SP3 and SP4 can be disposed adjacent to each other in the first direction, the first and third sub-pixels SP1 and SP3 can be disposed adjacent to each other in the second direction, and the second and fourth sub-pixels SP2 and SP4 can be disposed adjacent to each other in the second direction.

Here, the first sub-pixel SP1 can be a green sub-pixel, the second sub-pixel SP2 can be a white sub-pixel, the third sub-pixel SP3 can be a blue sub-pixel, and the fourth sub-pixel SP4 can be a red sub-pixel. However, embodiments of the present disclosure are not limited thereto. In other embodiments, the arrangement order of the red, green, blue, and white sub-pixels can be changed.

The first, second, third, and fourth sub-pixels SP1, SP2, SP3, and SP4 can have substantially the same area. However, embodiments of the present disclosure are not limited thereto. In other embodiments, the first, second, third, and fourth sub-pixels SP1, SP2, SP3, and SP4 can have different areas from each other.

Each of the first, second, third, and fourth sub-pixels SP1, SP2, SP3, and SP4 can include an emission area EA and a transparent area TA. The emission areas EA of the first, second, third, and fourth sub-pixels SP1, SP2, SP3, and SP4 can be disposed adjacent to each other. Accordingly, the emission areas EA of the first and second sub-pixels SP1 and SP2 can be disposed between the transparent areas TA of the first and second sub-pixels SP1 and SP2, and the emission areas EA of the third and fourth sub-pixels SP3 and SP4 can be disposed between the transparent areas TA of the third and fourth sub-pixels SP3 and SP4.

In each sub-pixel SP1, SP2, SP3, and SP4, the light-emitting diode De, the first, second, and third transistors T1, T2, and T3, and the storage capacitor Cst of FIG. 1 can be provided.

The light-emitting diode De can include a first electrode, a light-emitting layer, and a second electrode. The first electrode can be provided at each sub-pixel SP1, SP2, SP3, and SP4. The second electrode can be commonly provided over all sub-pixels SP1, SP2, SP3, and SP4. Here, the first electrode of each sub-pixel SP1, SP2, SP3, and SP4 can include two electrode patterns.

Meanwhile, an auxiliary electrode AE can be provided to partially overlap the first power line PL1. The auxiliary electrode AE can extend substantially in the first direction, and one end of the auxiliary electrode Ae can overlap the first power line PL1. The auxiliary electrode AE can be provided for each pixel and can be disposed to correspond to the transparent area TA of the fourth sub-pixel SP4.

The auxiliary electrode AE can be connected to the first power line PL1, and the second electrode of the light-emitting diode De can be connected to the auxiliary electrode AE. Accordingly, the second electrode of the light-emitting diode De can be electrically connected to the first power line PL1 through the auxiliary electrode AE. Therefore, the resistance of the second electrode can be reduced, and the luminance of the electroluminescent display device can be uniform.

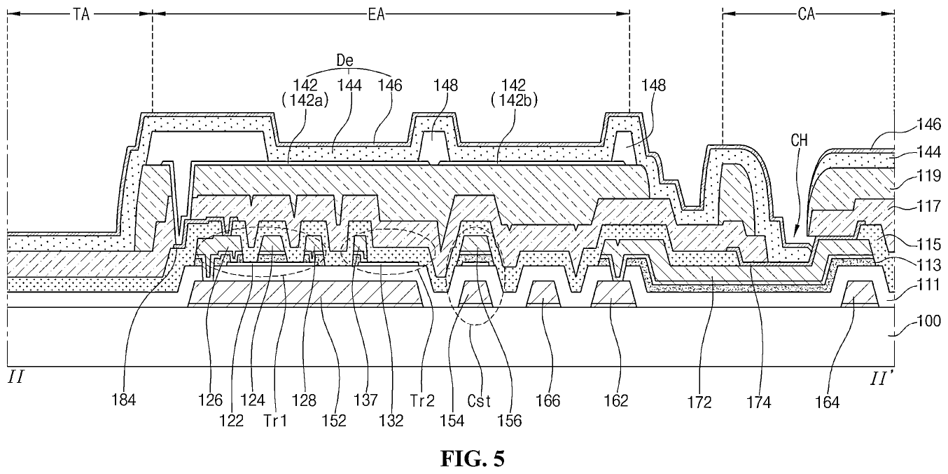

A cross-sectional configuration of another electroluminescent display device according to the embodiment of the present disclosure will be described with reference to FIG. 5.

FIG. 5 is a cross-sectional view of the line II-II′ of FIG. 4 and shows a cross-section of one sub-pixel. Another electroluminescent display device according to the embodiment of the present disclosure has substantially the same configuration as that of the previous embodiment of FIG. 3, except for a transparent area, a first electrode, and a connection electrode. The same parts as those of the previous embodiment are designated by the same reference signs, and explanation for the same parts may be shortened or omitted.

In FIG. 5, a sub-pixel of another electroluminescent display device according to the embodiment of the present disclosure can include an emission area EA, a transparent area TA, and a contact area CA provided on a substrate 100. A light-emitting diode De can be provided in the emission area EA, and an auxiliary electrode 172 and 174 can be provided in the contact area CA. The light-emitting diode De can include a first electrode 142, a light-emitting layer 144, and a second electrode 146, and the second electrode 146 can be electrically connected to a power line 162 through the auxiliary electrode 172 and 174.

Specifically, a light-blocking layer 152, the power line 162, a dummy pattern 164, a data line 166, and a first capacitor electrode 154 can be provided on the substrate 100. The substrate 100 can be formed of a transparent insulating material and for example, can be a glass substrate or a plastic substrate. Polyimide can be used for the plastic substrate, but embodiments are not limited thereto.

The light-blocking layer 152, the power line 162, the data line 166, and the first capacitor electrode 154 can be disposed in the emission area EA, and the dummy pattern 164 can be disposed in the contact area CA. The first capacitor electrode 154 can be connected to the light-blocking layer 152. In addition, the power line 162 can correspond to the first power line PL1 of FIG. 2 and can be a low potential power line providing a low potential voltage.

Meanwhile, according to the line II-II′ of FIG. 4, parts of the power line 162 and the data line 166 can also be disposed between the transparent area TA and the light-blocking layer 152, but can be omitted in FIG. 5 for convenience of illustration.

The dummy pattern 164 can be provided on the same layer and of the same material as the light-blocking layer 152, the power line 162, the data line 166, and the first capacitor electrode 154. The dummy pattern 164 can have an inclined side surface. That is, the side surface of the dummy pattern 164 can have an inclination with a predetermined angle with respect to the substrate 100.

The light-blocking layer 152, the power line 162, the dummy pattern 164, the data line 166, and the first capacitor electrode 154 can be formed of a conductive material such as metal. The light-blocking layer 152, the power line 162, the dummy pattern 164, the data line 166, and the first capacitor electrode 154 can be formed of one or more of: aluminum (Al), copper (Cu), molybdenum (Mo), titanium (Ti), chromium (Cr), nickel (Ni), tungsten (W), and an alloy thereof. For example, the light-blocking layer 152, the power line 162, the dummy pattern 164, the data line 166, and the first capacitor electrode 154 can have a double-layered structure including a lower layer of a molybdenum-titanium alloy (MoTi) and an upper layer of copper (Cu), and the upper layer can have a thicker thickness than the lower layer. However, embodiments of the present disclosure are not limited thereto. In other embodiments, the light-blocking layer 152, the power line 162, the dummy pattern 164, the data line 166, and the first capacitor electrode 154 can have a single-layered structure or a triple-layered structure.

A buffer layer 111 of an insulating material can be provided on the light-blocking layer 152, the power line 162, the dummy pattern 164, the data line 166, and the first capacitor electrode 154. The buffer layer 111 can be disposed over substantially an entire surface of the substrate 100. The buffer layer 111 can be formed of an inorganic insulating material, such as silicon oxide (SiO₂) or silicon nitride (SiNₓ), and can be formed as a single layer or multiple layers.

A first semiconductor layer 122 and a second semiconductor layer 132 can be patterned and provided on the buffer layer 111. The first semiconductor layer 122 and the second semiconductor layer 132 can be disposed to correspond to the emission area EA.

The first semiconductor layer 122 and the second semiconductor layer 132 can overlap the light-blocking layer 152. The light-blocking layer 152 can block light incident on the first semiconductor layer 122 and the second semiconductor layer 132, and reduce or prevent the first semiconductor layer 122 and the second semiconductor layer 132 from deteriorating due to the light. However, embodiments of the present disclosure are not limited thereto. In other embodiments, the first semiconductor layer 122 can overlap the light-blocking layer 152 and the second semiconductor layer 132 can be spaced apart from the light-blocking layer 152.

The first semiconductor layer 122 and the second semiconductor layer 132 can be formed of an oxide semiconductor material.

Alternatively, the first semiconductor layer 122 and the second semiconductor layer 132 can be formed of polycrystalline silicon. In this case, both end portions of each of the first semiconductor layer 122 and the second semiconductor layer 132 can be doped with impurities.

A gate insulation layer 113 of an insulating material can be disposed on the buffer layer 111 provided with the first semiconductor layer 122 and the second semiconductor layer 132 thereon. A first gate electrode 124, a first source electrode 126, a first drain electrode 128, a second source/drain electrode 137, a second capacitor electrode 156, and a first auxiliary electrode 172 can be disposed on the gate insulation layer 113. In addition, although not shown in the figure, a second gate electrode can be disposed on the gate insulation layer 113.

The gate insulation layer 113 can be patterned to have substantially the same shape as each of the first gate electrode 124, the first source electrode 126, the first drain electrode 128, the second source/drain electrode 137, the second capacitor electrode 156, and the first auxiliary electrode 172. However, embodiments of the present disclosure are not limited thereto. In other embodiments, the gate insulation layer 113 can be disposed over substantially the entire surface of the substrate 100.

The gate insulation layer 113 can be formed of an inorganic insulating material, such as silicon oxide (SiO₂) or silicon nitride (SiNₓ). When the first semiconductor layer 122 and the second semiconductor layer 132 are made of an oxide semiconductor material, the gate insulation layer 113 can be formed of silicon oxide (SiO₂).

Alternatively, when the first semiconductor layer 122 and the second semiconductor layer 132 are made of polycrystalline silicon, the gate insulation layer 113 can be formed of silicon oxide (SiO₂) or silicon nitride (SiNₓ).

The first gate electrode 124, the first source electrode 126, the first drain electrode 128, the second source/drain electrode 137, and the second capacitor electrode 156 can be disposed in the emission area EA, and the first auxiliary electrode 172 can be disposed in the contact area CA.

In this case, the first gate electrode 124 can correspond to a center of the first semiconductor layer 122 and can be disposed between the first source electrode 126 and the first drain electrode 128. The first source electrode 126 and the first drain electrode 128 can be disposed to correspond to both end portions of the first semiconductor layer 122 and can be in contact with the both end portions of the first semiconductor layer 122 through contact holes provided in the gate insulation layer 113, respectively.

Although not shown in the figure, the second gate electrode can be disposed to correspond to a center of the second semiconductor layer 132. The second source/drain electrode 137 can be disposed to an end portion of the second semiconductor layer 132 and can be in contact with the end portion of the semiconductor layer 132 through a contact hole of the gate insulation layer 113.

In addition, the second capacitor electrode 156 can overlap the first capacitor electrode 154. The first capacitor electrode 154 and the second capacitor electrode 156 overlapping each other can constitute a storage capacitor Cst with the buffer layer 111 and the gate insulation layer 113 interposed therebetween as a dielectric.

A semiconductor pattern can be provided between the first capacitor electrode 154 and the second capacitor electrode 156. The semiconductor pattern can be formed of the same material and on the same layer as the first and second semiconductor layers 122 and 132. That is, the semiconductor pattern can overlap the first capacitor electrode 154 and the second capacitor electrode 156 and can be located between the buffer layer 111 and the gate insulation layer 113.

Meanwhile, the first auxiliary electrode 172 can overlap the power line 162 and be in contact with the power line 162 through a contact hole provided in the gate insulation layer 113 and buffer layer 111. Further, the first auxiliary electrode 172 can overlap the dummy pattern 164 and have an inclined surface, that is, an inclined step surface due to the dummy pattern 164. In one embodiment, the first auxiliary electrode 172 does not contact the second electrode 146. Rather, the inclined surface of the second auxiliary electrode 174 contacts the end of the second electrode 146 and the flat surface of the second auxiliary electrode 174 contacts the first auxiliary electrode 172 thereby electrically connecting the power line 162 to the second electrode 146.

The first gate electrode 124, the first source electrode 126, the first drain electrode 128, the second source/drain electrode 137, the second capacitor electrode 156, and the first auxiliary electrode 172 can be formed of a conductive material such as metal. The first gate electrode 124, the first source electrode 126, the first drain electrode 128, the second source/drain electrode 137, the second capacitor electrode 156, and the first auxiliary electrode 172 can be formed of one or more of: aluminum (Al), copper (Cu), molybdenum (Mo), titanium (Ti), chromium (Cr), nickel (Ni), tungsten (W), and an alloy thereof. For example, the first gate electrode 124, the first source electrode 126, the first drain electrode 128, the second source/drain electrode 137, the second capacitor electrode 156, and the first auxiliary electrode 172 can have a double-layered structure, including a lower layer of a molybdenum-titanium alloy (MoTi) and an upper layer of copper (Cu), and the upper layer can be thicker than the lower layer. However, embodiments of the present disclosure are not limited thereto. In other embodiments, the first gate electrode 124, the first source electrode 126, the first drain electrode 128, the second source/drain electrode 137, the second capacitor electrode 156, and the first auxiliary electrode 172 can have a single-layered structure or a triple-layered structure.

The first semiconductor layer 122, the first gate electrode 124, the first source electrode 126, and the first drain electrode 128 can form a first thin film transistor Tr1. The second semiconductor layer 132, the second gate electrode, and the second source/second drain electrode 137 can form a second thin film transistor Tr2.

The first thin film transistor Tr1 can be the driving transistor T2 of FIG. 1, and the second thin film transistor Tr2 can be the sensing transistor T3 of FIG. 1. Meanwhile, at least one thin film transistor having substantially the same structure as the first and second thin film transistors Tr1 and Tr2 can be further provided on the substrate 100.

Here, the first source electrode 126 can be in contact with the light-blocking layer 152 through a contact hole provided in the gate insulation layer 113 and the buffer layer 111.

A first passivation layer 115 of an insulating material can be provided on the first gate electrode 124, the first source electrode 126, the first drain electrode 128, the second source/drain electrode 137, the second capacitor electrode 156, and the first auxiliary electrode 172. The first passivation layer 115 can be disposed over substantially the entire surface of the substrate 100. The first passivation layer 115 can be an interlayer insulation layer and can be formed of an inorganic insulating material, such as silicon oxide (SiO₂) or silicon nitride (SiNₓ).

The first passivation layer 115 can have a contact hole exposing the first source electrode 126 in the emission area EA and can have a contact hole exposing the first auxiliary electrode 172 in the contact area CA.

A connection electrode 184 and a second auxiliary electrode 174 can be provided on the first passivation layer 115. The connection electrode 184 can be disposed in the emission area EA and the second auxiliary electrode 174 can be disposed in the contact area CA. In the emission area EA, the connection electrode 184 can be in contact with the first source electrode 126 through a contact hole provided in the first passivation layer 115. In the contact area CA, the second auxiliary electrode 174 can be in contact with the first auxiliary electrode 172 through a contact hole provided in the first passivation layer 115. The second auxiliary electrode 174 can have an inclined surface, that is, an inclined step surface due to the inclined side surface of the dummy pattern 164. A thickness of the second auxiliary electrode 174 can be smaller than a thickness of the first auxiliary electrode 172, and a width of the second auxiliary electrode 174 can be narrower than a width of the first auxiliary electrode 172. The second auxiliary electrode 174 can overlap the dummy pattern 164.

The connection electrode 184 and the second auxiliary electrode 174 can be formed of a conductive material such as metal. For example, the connection electrode 184 and the second auxiliary electrode 174 can be formed of one or more of: molybdenum (Mo), titanium (Ti), chromium (Cr), nickel (Ni), tungsten (W), and an alloy thereof. Alternatively, the connection electrode 184 and the second auxiliary electrode 174 can be formed of a transparent conductive material. For example, the connection electrode 184 and the second auxiliary electrode 174 can be formed of indium tin oxide (ITO) or indium zinc oxide (IZO).

Here, the first and second auxiliary electrodes 172 and 174 can correspond to the auxiliary electrode AE of FIG. 2. In one embodiment, and the second auxiliary electrode 174 can be omitted.

A second passivation layer 117 of an insulating material can be provided on the connection electrode 184 and the second auxiliary electrode 174. The second passivation layer 117 can be disposed over substantially the entire surface of the substrate 100. The second passivation layer 117 can be a protection layer. The second passivation layer 117 can be formed of an inorganic insulating material, such as silicon oxide (SiO₂) or silicon nitride (SiNₓ). A thickness of the second passivation layer 117 can be thicker than a thickness of the first passivation layer 115.

The second passivation layer 117 can have a contact hole CH exposing the second auxiliary electrode 174 in the contact area CA. An undercut structure where a bottom surface of the second passivation layer 117 is exposed can be provided on at least one side of the contact hole CH.

An overcoat layer 119 of an insulating material can be provided on the second passivation layer 117. The overcoat layer 119 can be disposed over substantially in the emission area EA and the contact area CA and can be removed in the transparent area TA to thereby expose the second passivation layer 117 in the transparent area TA. The overcoat layer 119 and the second passivation layer 117 can have a contact hole exposing the connection electrode 184 in the emission area EA. The contact hole exposing the connection electrode 184 can be spaced apart from the contact hole exposing the first source electrode 126.

In addition, the overcoat layer 119 can have a contact hole exposing the second auxiliary electrode 174 in the contact area CA. In this case, the overcoat layer 119 can cover the second passivation layer 117 at the side provided with the undercut structure and can expose the second passivation layer 117 at a side provided without the undercut structure.

The overcoat layer 119 can be a planarization layer. The overcoat layer 119 can be formed of an organic insulating material such as photosensitive acrylic polymer (photo acryl). The overcoat layer 119 can eliminate a step difference due to the layers thereunder and can have a substantially flat top surface. However, embodiments of the present disclosure are not limited thereto.

The first electrode 142 can be disposed on the overcoat layer 119 in the emission area EA and can be formed of a conductive material having relatively high work function.

For example, the first electrode 142 can include a transparent conductive material such as indium tin oxide (ITO) or indium zinc oxide (IZO) or include titanium (Ti). However, embodiments of the present disclosure are not limited thereto.

Meanwhile, as described above, the electroluminescent display device according to the embodiment of the present disclosure can be a top emission type display device, in which light from the light-emitting layer 144 is output toward a direction opposite the substrate 100, that is, output to the outside through the second electrode 146. In this case, the first electrode 142 can have a multi-layered structure including a material with relatively high reflectance.

The first electrode 142 can be divided into two patterns. That is, the first electrode 142 can include a first electrode pattern 142a and a second electrode pattern 142b. The first electrode pattern 142a can be in contact with a first end of the connection electrode 184 through the contact hole provided in the overcoat layer 119 and the second passivation layer 117. In addition, although not shown in the figure, the second electrode pattern 142b can be in contact with a second end of the connection electrode 184 through another contact hole provided in the overcoat layer 119 and the second passivation layer 117. Accordingly, the first electrode pattern 142a and the second electrode pattern 142b can be electrically connected to the first source electrode 126 through the connection electrode 184.

The first and second connection patterns 142a and 142b can minimize or at least reduce deterioration in image quality by allowing partial light emission through repair when a defect occurs. Specifically, when the defect occurs in a portion corresponding to the first electrode pattern 142a during a manufacturing process or during operation, the first end of the connection electrode 184 connected to the first electrode pattern 142a can be cut using a laser. Accordingly, while light is not emitted in the portion corresponding to the first electrode pattern 142a, light can be emitted in a portion corresponding to the second electrode pattern 142b, thereby preventing a defect in which an entire sub-pixel does not emit light.

A bank 148 of an organic insulating material can be disposed on the first electrode 142. The bank 148 can overlap edges of each of the first and second electrode patterns 142a and 142b and cover the edges of each of the first and second electrode patterns 142a and 142b. The bank 148 can expose a central portion of each of the first and second electrode patterns 142a and 142b.

The bank 148 may not be provided in the transparent area TA and the contact area CA.

Next, the light-emitting layer 144 can be provided on the first electrode 142 exposed by the bank 148, that is, on the first and second electrode patterns 142a and 142b. The light-emitting layer 144 can be disposed over substantially the entire surface of the substrate 100. Accordingly, in the emission area EA, the light-emitting layer 144 can be in contact with the first and second electrode patterns 142a and 142b and also in contact with side and top surfaces of the bank 148. Additionally, in the contact area CA, the light-emitting layer 144 can be in contact with top and side surfaces of the overcoat layer 119 and can also be in contact with exposed top and side surfaces of the second passivation layer 117 and a top surface of the second auxiliary electrode 174. In the contact area CA, the light-emitting layer 144 can be separated by the undercut structure.

Meanwhile, the light-emitting layer 144 can also be provided in the transparent area TA. In the transparent area TA, the light-emitting layer 144 can be in contact with the top surface of the second passivation layer 117.

The light-emitting layer 144 can emit white light and can include at least one hole auxiliary layer, at least one light-emitting material layer, and at least one electron auxiliary layer constituting one light-emitting unit. The hole auxiliary layer can include at least one of a hole injection layer (HIL) and a hole transport layer (HTL). The electron auxiliary layer can include at least one of an electron injection layer (EIL) and an electron transport layer (ETL).

The light-emitting layer 144 can have a stack structure in which two or more light-emitting units emitting light of different colors are stacked, and a charge generation layer (CGL) can be provided between two light-emitting units.

The second electrode 146 of a conductive material with relatively low work function can be provided on the light-emitting layer 144. The second electrode 146 can be disposed over substantially the entire surface of the substrate 100.

The second electrode 146 can be formed of aluminum (Al), magnesium (Mg), silver (Ag), or an alloy thereof. In this case, the second electrode 146 can have a relatively thin thickness such that light from the light-emitting layer 144 can be transmitted therethrough. For example, the second electrode 146 can have a thickness of 5 nm to 10 nm, but embodiments of the present disclosure are not limited thereto.

Alternatively, the second electrode 146 can be formed of a transparent conductive material such as IGO or IZO.

The second electrode 146 can be in contact with a top surface of the light-emitting layer 144. In the contact area CA, the second electrode 146 can be separated by the undercut structure and be in contact with the second auxiliary electrode 174 under the undercut structure. This will be described in detail later.

The first electrode 142, the light-emitting layer 144, and the second electrode 146 of the emission area EA can constitute the light-emitting diode De. Here, the first electrode 142 can serve as an anode, and the second electrode 146 can serve as a cathode. However, embodiments of the present disclosure are not limited thereto.

Meanwhile, although not shown in the figure, a capping layer and an encapsulation layer can be sequentially formed on the second electrode 146 and disposed over substantially the entire surface of the substrate 100.

As such, in another electroluminescent display device according to the embodiment of the present disclosure, each sub-pixel can include the emission area EA and the transparent area TA, so that the surrounding environment information such as backgrounds can be shown together through the transparent area TA while displaying a color image through the emission area EA.

In addition, by forming the undercut structure in the contact area CA, the second electrode 146 can be in direct contact with the auxiliary electrode 172 and 174. For example, the second electrode 146 can be in direct contact with the inclined surface of the auxiliary electrode 172 and 174, thereby improving the contact properties between the second electrode 146 and the auxiliary electrode 172 and 174. Accordingly, a difference in resistance of the second electrode 146 can be prevented, so that the luminance of the electroluminescent display device can be made uniform.

The configuration of the contact area according to embodiments of the present disclosure will be described in more detail with reference to accompanying drawings.

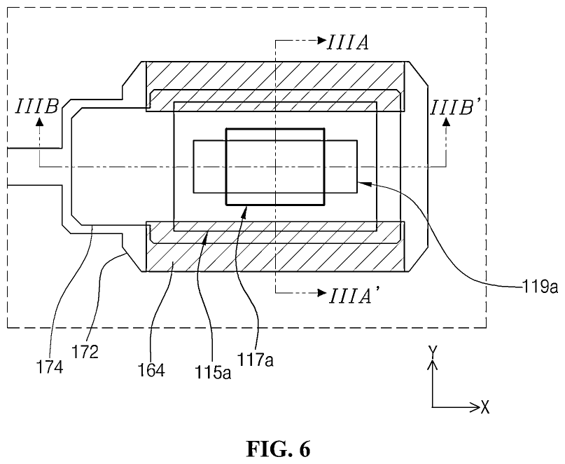

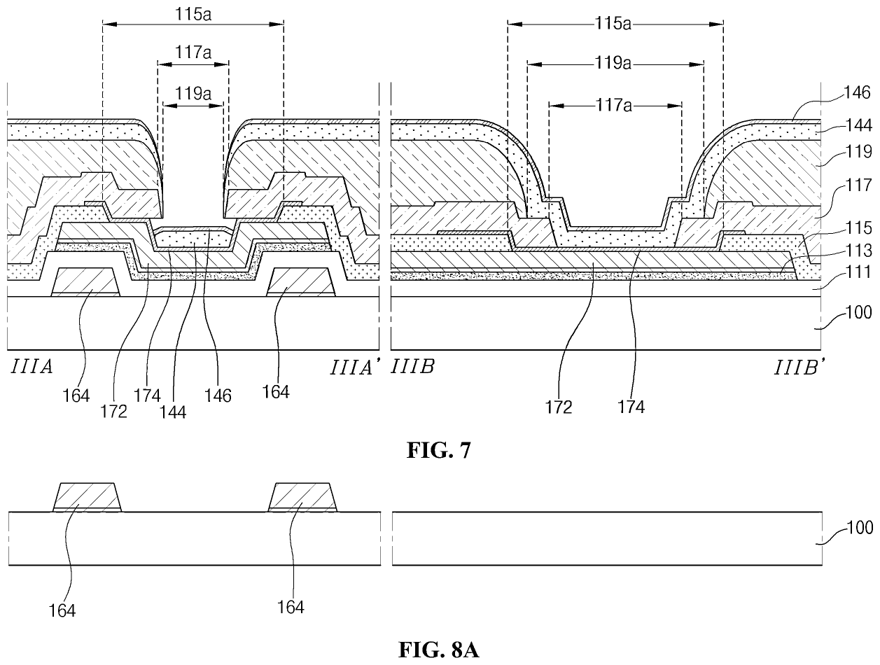

FIG. 6 is a schematic plan view of a contact area of an electroluminescent display device according to a first embodiment of the present disclosure, and FIG. 7 is a cross-sectional view corresponding to the line IIIA-IIIA′ and the line IIIB-IIIB′ of FIG. 6 according to one embodiment.

As shown in FIG. 6 and FIG. 7, in the electroluminescent display device according to the first embodiment of the present disclosure, the dummy pattern 164 can be provided under the first and second auxiliary electrodes 172 and 174, so that the first and second auxiliary electrodes 172 and 174 can have the inclined surfaces due to the step difference of the dummy pattern 164. The second passivation layer 117, which is an insulation layer over the first and second auxiliary electrodes 172 and 174, can have the undercut structure.

Specifically, at least one dummy pattern 164 can be provided on the substrate 100. The dummy pattern 164 can have a rod shape extending in the first direction, which is the X direction, or in the second direction, which is the Y direction. For example, a couple of rod-shaped dummy patterns 164 can extend in the first direction and be spaced apart from each other in the second direction.

However, embodiments of the present disclosure are not limited thereto, the shape, the extension direction, and the separation direction can be changed. Alternatively, the dummy pattern 164 can have a U-like shape.

The dummy pattern 164 can have an inclined side surface. The side surface of the dummy pattern 164 can have an inclination with a predetermined angle with respect to the substrate 100. That is, the side surface of the dummy pattern 164 can have an angle greater than 0 degrees and less than or equal to 90 degrees with respect to the substrate 100.

The buffer layer 111 can be provided on the dummy pattern 164. The buffer layer 111 can have a step difference due to the dummy pattern 164.

The gate insulation layer 113 and the first auxiliary electrode 172 can be sequentially provided on the buffer layer 111. The gate insulation layer 113 and the first auxiliary electrode 172 can overlap the dummy pattern 164 and can have a step difference due to the dummy pattern 164. The first auxiliary electrode 172 can have an inclined step surface due to the step difference, and a top surface of the first auxiliary electrode 172 can also have an inclined step surface.

The first passivation layer 115 can be provided on the first auxiliary electrode 172. The first passivation layer 115 can have a first contact hole 115a exposing a top surface of the first auxiliary electrode 172. The first contact hole 115a can expose the inclined step surface of the first auxiliary electrode 172. The first contact hole 115a can overlap the dummy pattern 164.

The second auxiliary electrode 174 can be provided on the first passivation layer 115. The second auxiliary electrode 174 can have a larger area than the first contact hole 115a and be in contact with the first auxiliary electrode 172 exposed through the first contact hole 115a. The second auxiliary electrode 174 can have a step difference due to the dummy pattern 164. The second auxiliary electrode 174 can have an inclined step surface due to the step difference, and the top surface of the second auxiliary electrode 174 can also have an inclined step surface. The second auxiliary electrode 174 can overlap the dummy pattern 164. The second auxiliary electrode 174 can be omitted.

The second passivation layer 117 can be provided on the second auxiliary electrode 174. The second passivation layer 117 can have a second contact hole 117a exposing the second auxiliary electrode 174. The second contact hole 117a can have a smaller area than the first contact hole 115a and can be disposed in the first contact hole 115a.

An undercut structure where the bottom surface of the second passivation layer 117 is exposed can be provided on at least one side of the second contact hole 117a, for example, at upper and lower sides facing each other along the second direction in FIG. 6. The undercut structure can be provided to correspond to the dummy pattern 164 and the inclined step surfaces of the first and second auxiliary electrodes 172 and 174. The inclined step surface of the second auxiliary electrode 174 can be exposed under the undercut structure.

On the other hand, the undercut structure may not be provided at left and right sides of the second contact hole 117a facing each other along the first direction in FIG. 6.

However, embodiments of the present disclosure are not limited thereto, and the location where the undercut structure is provided can vary. For example, the undercut structure can be provided at the left and right sides of the second contact hole 117a facing each other along the first direction in FIG. 6. Alternatively, the undercut structure can be provided at three sides of the upper, lower, left, and right sides of the second contact hole 117a. In this case, the dummy pattern 164 can have a U-like shape corresponding to the undercut structure.

The overcoat layer 119 can be provided on the second passivation layer 117. The overcoat layer 119 can have a substantially flat top surface and have a third contact hole 119a exposing the second passivation layer 117 and the second auxiliary electrode 174.

The third contact hole 119a can have a smaller area than the first contact hole 115a and be disposed in the first contact hole 115a. In addition, the third contact hole 119a can overlap the second contact hole 117a, and the third contact hole 119a can have a wider width than the second contact hole 117a in the first direction and a narrower width than the second contact hole 117a in the second direction.

Accordingly, the overcoat layer 119 can expose side and top surfaces of the second passivation layer 117 facing each other in the first direction corresponding to the second contact hole 117a where the undercut structure is not provided. The overcoat layer 119 can cover side and top surfaces of the second passivation layer 117 facing each other in the second direction corresponding to the second contact hole 117a where the undercut structure is provided. In this case, the bottom surface of the overcoat layer 119 corresponding to the undercut structure can be exposed. That is, a part of the bottom surface of the overcoat layer 119 can be exposed at upper and lower sides of the third contact hole 119a facing each other along the second direction in FIG. 6.

The light-emitting layer 144 and the second electrode 146 can be sequentially provided on the overcoat layer 119. The light-emitting layer 144 and the second electrode 146 can cover the top and side surfaces of the overcoat layer 119. The light-emitting layer 144 and the second electrode 146 can also be disposed on the second passivation layer 117 and the second auxiliary electrode 174 exposed through the third contact hole 119a, and the light-emitting layer 144 can be in contact with the second auxiliary electrode 174 through the third contact hole 119a.

At the side surface of the overcoat layer 119 corresponding to the undercut structure, the light-emitting layer 144 and the second electrode 146 can have a thickness that gradually decreases as they approach or get closer to the substrate 100 and then be cut off by the undercut structure. Accordingly, portions of the light-emitting layer 144 and the second electrode 146 over the side surface of the overcoat layer 119 corresponding to the undercut structure can be separated from portions of the light-emitting layer 144 and the second electrode 146 over the second auxiliary electrode 174, respectively. On the other hand, portions of the light-emitting layer 144 and the second electrode 146 over the side surface of the overcoat layer 119 that does not correspond to the undercut structure can be connected to the portions of the light-emitting layer 144 and the second electrode 146 over the second auxiliary electrode 174, respectively, without separation.

Namely, corresponding to the third contact hole 119a, the portions of the light-emitting layer 144 and the second electrode 146 can be connected to the portions thereof in the first direction, respectively, and be separated to the portions thereof in the second direction, respectively. The separated portions of the light-emitting layer 144 and the second electrode 146 can be in contact with the inclined step surface of the second auxiliary electrode 174 at a location that is under the undercut structure. Meanwhile, when the second auxiliary electrode 174 is omitted, the separated portions of the light-emitting layer 144 and the second electrode 146 can be in contact with the inclined step surface of the first auxiliary electrode 172 under the undercut structure.

In this case, the total thickness of the light-emitting layer 144 and the second electrode 146 can be smaller than the step difference of the second auxiliary electrode 174. In addition, the total thickness of the light-emitting layer 144 and the second electrode 146 can be smaller than the thickness of the dummy pattern 164.

As such, in the electroluminescent display device according to the first embodiment of the present disclosure, the structure such as the dummy pattern 164 can be provided under the first and second auxiliary electrodes 172 and 174, so that the first and second auxiliary electrodes 172 and 174 can be configured to have the inclined surface, that is, the inclined step surface due to the step difference of the dummy pattern 164. In addition, the second passivation layer 117 over the first and second auxiliary electrodes 172 and 174 can be configured to have the undercut structure. Accordingly, each of the light-emitting layer 144 and the second electrode 146 over the second passivation layer 117 in the contact area can be separated from the light-emitting layer 144 and the second electrode 146 in the emission area by the undercut structure, and the separated second electrode 146 can be in direct contact with the inclined step surface of the first or second auxiliary electrode 172 or 174 under the undercut structure, thereby improving the contact properties between the second electrode 146 and the first and second auxiliary electrodes 172 and 174.

As described above, the dummy pattern 164 and the undercut structure can have the U-like shape in plan, and in this case, the contact area between the second electrode 146 and the first or second auxiliary electrode 172 or 174 can increase, thereby further improving the contact properties.

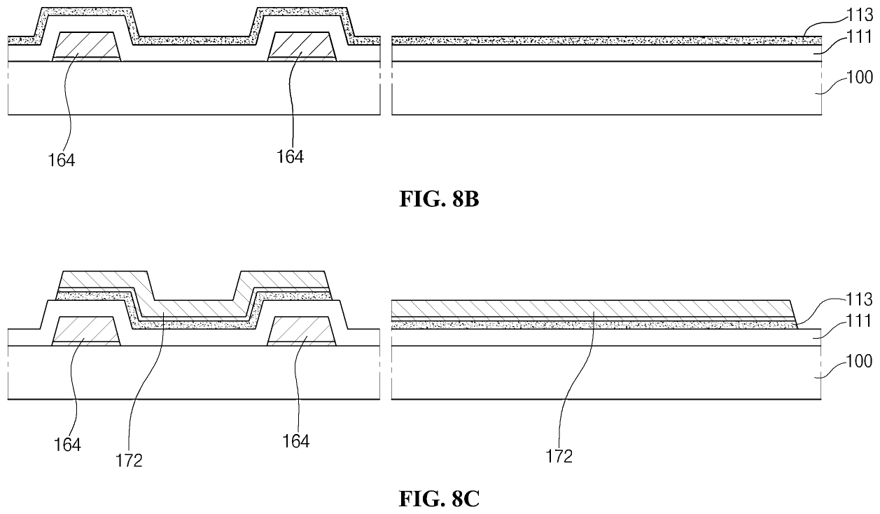

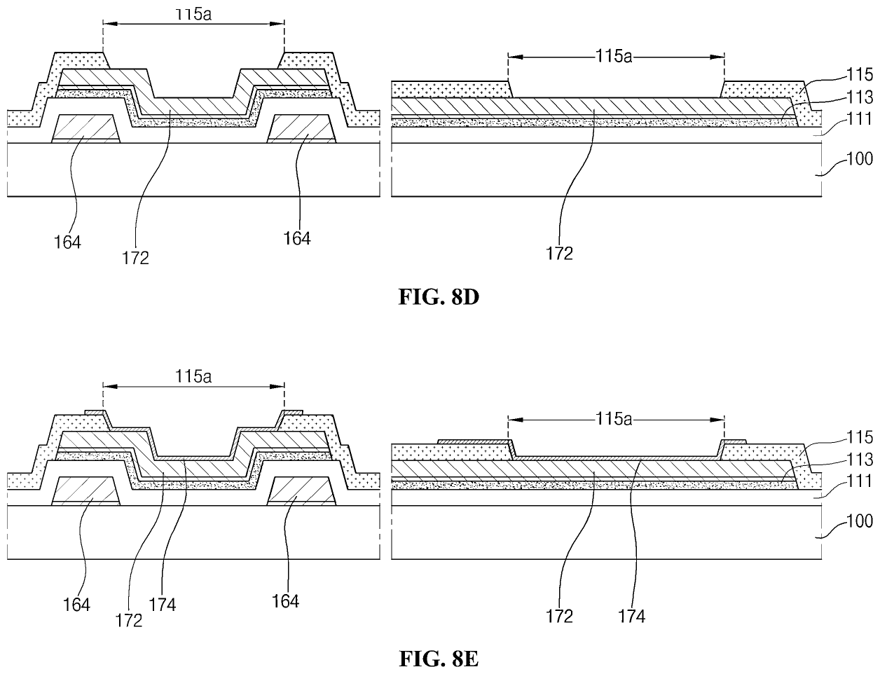

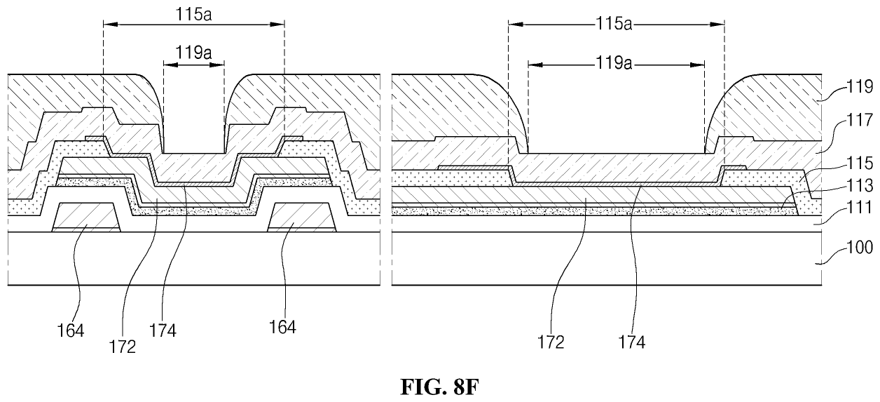

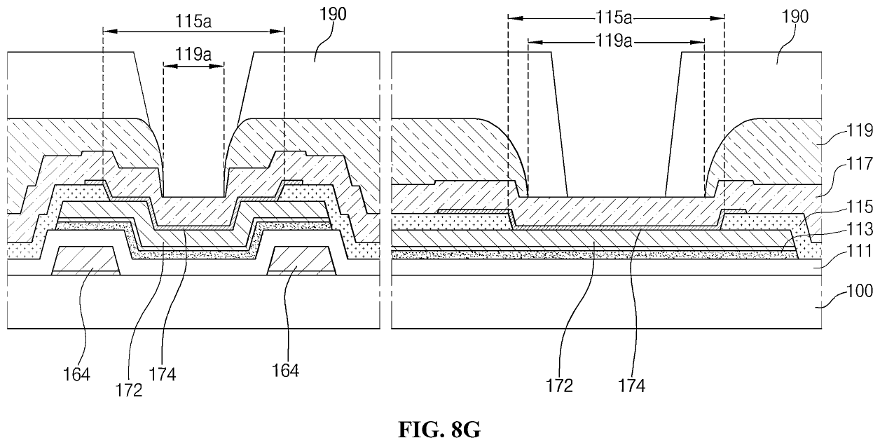

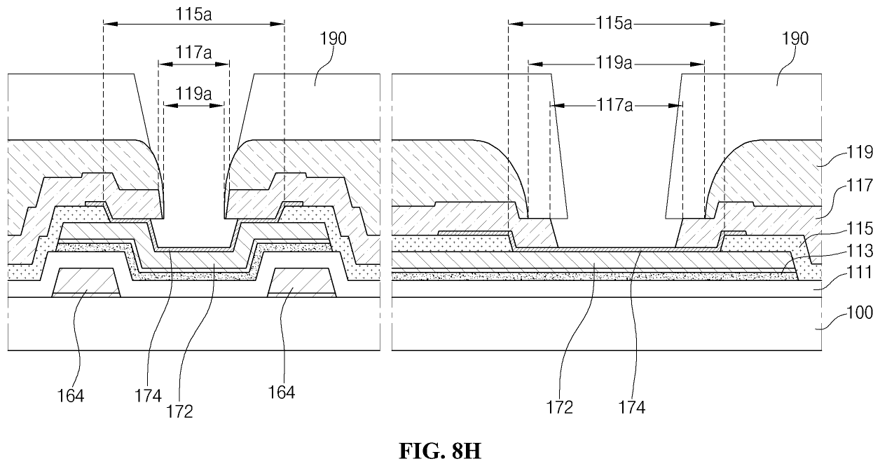

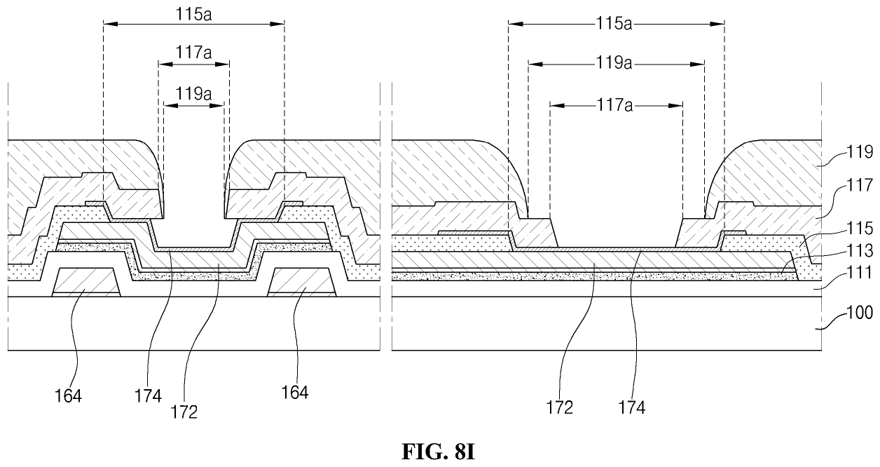

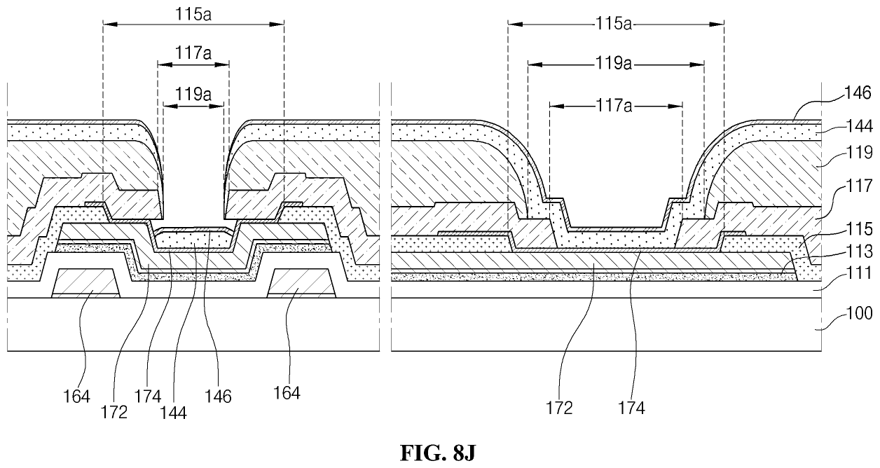

A method of manufacturing the electroluminescent display device according to the first embodiment of the present disclosure will be described in detail with reference to FIGS. 8A to 8J.

FIGS. 8A to 8J are schematic cross-sectional views of a contact area in steps of manufacturing an electroluminescent display device according to the first embodiment of the present disclosure, and will be described with reference to FIG. 5 together.

First, in FIG. 8A, the dummy pattern 164 can be formed on the substrate 100 by depositing a conductive material and patterning it through a photolithography process.

Here, the photolithography process can include steps of applying photoresist on a thin film to be patterned, light-exposing and developing the photoresist, etching the thin film, and stripping the photoresist. The etching step can be carried out through a wet etching process using etchant or a dry etching process using gases. When the thin film to be patterned is formed of a material having photosensitivity, only the light-exposing and developing steps can be performed without steps of applying the photoresist and etching the thin film.

Meanwhile, the light-blocking layer 152, the power line 162, the data line 166, and the first capacitor electrode 154 of FIG. 5 can be formed together with the dummy pattern 164.

Next, in FIG. 8B, the buffer layer 111 can be formed on the dummy pattern 164 by depositing an inorganic insulating material over substantially the entire surface of the substrate 100. Then, although not shown in the figure, the first and second semiconductor layers 122 and 132 of FIG. 5 can be formed on the buffer layer 111 by depositing a semiconductor material and patterning it through a photolithography process, and the gate insulation layer 113 can be formed on the buffer layer 111 provided with the first and second semiconductor layers 122 and 132 of FIG. 5 thereon by depositing an inorganic insulating material over substantially the entire surface of the substrate 100.

The buffer layer 111 and the gate insulation layer 113 can cover the dummy pattern 164 and have the step differences due to the dummy pattern 164. Accordingly, the buffer layer 111 and the gate insulation layer 113 can have uneven top surfaces.

Then, although not shown in the figure, the contact holes exposing the first and second semiconductor layers 122 and 132 of FIG. 5 can be formed by patterning the gate insulation layer 113 through a photolithography process, and the contact holes respectively exposing the power line 162 and the light-blocking layer 152 of FIG. 5 can be formed by patterning the gate insulation layer 113 and the buffer layer 111 through the photolithography process.

Next, in FIG. 8C, the first auxiliary electrode 172 can be formed on the gate insulation layer 113 by depositing a conductive material and patterning it through a photolithography process. At this time, the gate insulation layer 113 can also be patterned to have the same shape as the first auxiliary electrode 172.

Here, the first auxiliary electrode 172 and the gate insulation layer 113 can be patterned by a dry etching process. Alternatively, the first auxiliary electrode 172 can be patterned by a wet etching process, and the gate insulation layer 113 can be patterned by a dry etching process. However, embodiments of the present disclosure are not limited thereto.

The first auxiliary electrode 172 and the gate insulation layer 113 can overlap the dummy pattern 164 and have the step differences due to the dummy pattern 164. The first auxiliary electrode 172 can have the inclined step surface due to the step difference, and the top surface of the first auxiliary electrode 172 can also have the inclined step surface.

Meanwhile, the first gate electrode 124, the first source electrode 126, the first drain electrode 128, the second source/drain electrode 137, and the second capacitor electrode 156 of FIG. 5 can also be formed together with the first auxiliary electrode 172.

Next, in FIG. 8D, the first passivation layer 115 can be formed on the first auxiliary electrode 172 by depositing an inorganic insulating material, and the first contact hole 115a exposing the first auxiliary electrode 115 can be formed by patterning the first passivation layer 115 through a photolithography process. The first contact hole 115a can expose the inclined step surface of the first auxiliary electrode 172.

At this time, the contact hole exposing the first source electrode 126 of FIG. 5 can also be formed together with the first contact hole 115a.

Next, in FIG. 8E, the second auxiliary electrode 174 can be formed on the first passivation layer 115 by depositing a conductive material and patterning it through a photolithography process. At this time, the connection electrode 184 of FIG. 5 can also be formed together with the second auxiliary electrode 174.

The second auxiliary electrode 174 can overlap the first auxiliary electrode 172 and be in contact with the first auxiliary electrode 172 through the first contact hole 115a. The second auxiliary electrode 174 can have the step difference due to the dummy pattern 164. The second auxiliary electrode 174 can have the inclined step surface due to the step difference, and the top surface of the second auxiliary electrode 174 can also have the inclined step surface. In addition, the second auxiliary electrode 174 can overlap the dummy pattern 164.

Next, in FIG. 8F, the second passivation layer 117 can be formed on the second auxiliary electrode 174 by depositing an inorganic insulating material, and the overcoat layer 119 can be formed on the second passivation layer 117 by applying an organic insulating material. Then, the third contact hole 119a exposing the second passivation layer 117 can be formed by patterning the overcoat layer 119 through a photolithography process.

The third contact hole 119a can have a smaller area than the first contact hole 115a and be disposed in the first contact hole 115a. In this case, the second passivation layer 117 can have the inclined step surface due to the dummy pattern 164, and the overcoat layer 119 can cover the inclined step surface of the second passivation layer 117.

Here, the overcoat layer 119 can be formed of a material having negative photosensitivity in which a portion exposed to light remains after developing. However, embodiments of the present disclosure are not limited thereto. In other embodiments, the overcoat layer 119 can be formed of a material having positive photosensitivity in which a portion exposed to light is removed after developing.

Meanwhile, when the third contact hole 119a is formed, a portion of the overcoat layer 119 corresponding to the transparent area TA of FIG. 5 can also be removed.

Next, in FIG. 8G, a photoresist pattern 190 can be formed on the overcoat layer 119 having the third contact hole 119a by applying photoresist and light-exposing and developing it. The photoresist pattern 190 can expose the second passivation layer 117. In an area where the dummy pattern 164 is provided, edges of the photoresist pattern 190 can be disposed on the overcoat layer 119, and the photoresist pattern 190 can expose the side surface or the top and side surfaces of the overcoat layer 119. On the other hand, in an area where the dummy pattern 164 is not provided, edges of the photoresist pattern 190 can be disposed on the second passivation layer 117, and the photoresist pattern 190 can cover the top and side surfaces of the overcoat layer 119.

Next, in FIG. 8H, the second contact hole 117a can be formed by selectively removing the exposed second passivation layer 117 using the photoresist pattern 190 as an etch mask. Here, the second passivation layer 117 can be removed through a wet etching process.

The second contact hole 117a can have a smaller area than the first contact hole 115a and be disposed in the first contact hole 115a. In the area where the dummy pattern 164 is provided, the second passivation layer 117 under the overcoat layer 119 can be over-etched, and the width of the second contact hole 117a can be greater than the width of the third contact hole 119a, thereby forming the undercut structure where the bottom surface of the overcoat layer 119 and the bottom surface of the second passivation layer 117 are exposed. On the other hand, in the area where the dummy pattern 164 is not provided, even though the second passivation layer 117 under the photoresist pattern 190 is over-etched, the width of the second contact hole 117a can be smaller than the width of the third contact hole 119a, so that the undercut structure may not be formed.

Next, in FIG. 8I, the photoresist pattern 190 of FIG. 8H can be stripped and removed.

Then, although not shown in the figure, the first electrode 142 and the bank 148 of FIG. 5 can be formed on the overcoat layer 119.

Next, in FIG. 8J, the light-emitting layer 144 and the second electrode 146 can be sequentially formed on the overcoat layer 119. In this case, the light-emitting layer 144 and the second electrode 146 can be formed over substantially the entire surface of the substrate 100 through a vacuum evaporation method. However, embodiments of the present disclosure are not limited thereto.

In the area where the dummy pattern 164 is provided, each of the light-emitting layer 144 and the second electrode 146 can be cut off by the undercut structure, and the portions of the light-emitting layer 144 and the second electrode 146 in the second and third contact holes 117a and 119a can be separated from the portions of the light-emitting layer 144 and the second electrode 146 over the overcoat layer 119. In this case, the separated portions of the light-emitting layer 144 and the second electrode 146 in the second and third contact holes 117a and 119a can be in contact with the inclined step surface of the second auxiliary electrode 174.

On the other hand, in the area where the dummy pattern 164 is not provided, the light-emitting layer 144 and the second electrode 146 may not be cut off, and the portions of the light-emitting layer 144 and the second electrode 146 in the second and third contact holes 117a and 119a can be connected to the portions of the light-emitting layer 144 and the second electrode 146 over the overcoat layer 119.

Accordingly, the second electrode 146 can be electrically connected to the power line 162 of FIG. 5 through the first and second auxiliary electrodes 172 and 174.

As such, in the method of manufacturing the electroluminescent display device according to the first embodiment of the present disclosure, by providing the dummy pattern 164 under the first and second auxiliary electrodes 172 and 174, the first and second auxiliary electrodes 172 and 174 can be configured to have the inclined step surface. In addition, since the second contact hole 117a of the second passivation layer 117 is formed after forming the third contact hole 119a of the overcoat layer 119, the undercut structure can be provided in the second passivation layer 117, and the light-emitting layer 144 and the second electrode 146 can be separated by the undercut structure, so that the separated second electrode 146 can be in contact with the inclined step surface. Accordingly, the contact properties between the second electrode 146 and the first and second auxiliary electrodes 172 and 174 can be improved.

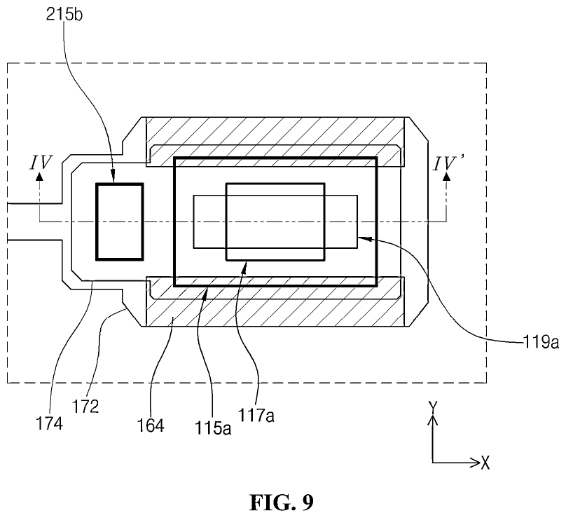

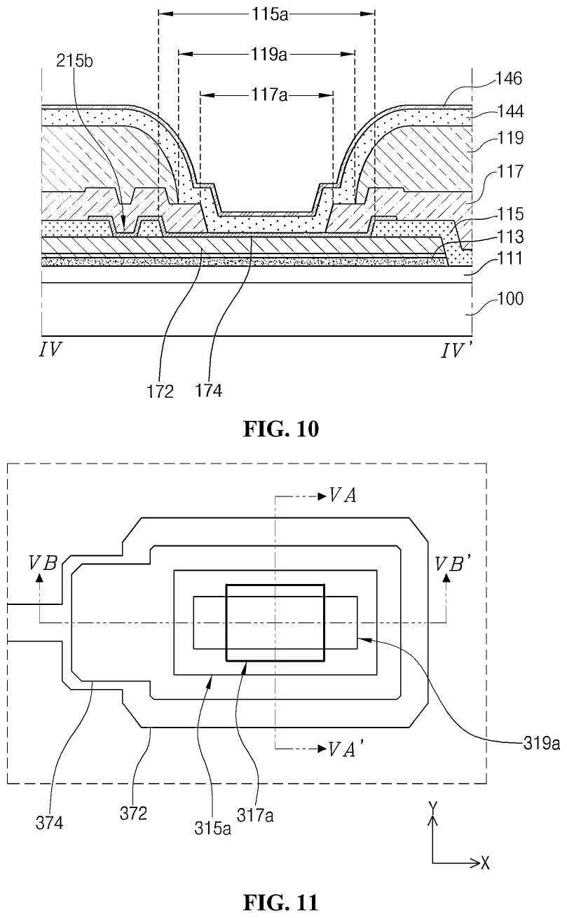

FIG. 9 is a schematic plan view of a contact area of an electroluminescent display device according to a second embodiment of the present disclosure, and FIG. 10 is a cross-sectional view corresponding to the line IV-IV′ of FIG. 9. The electroluminescent display device according to the second embodiment of the present disclosure has substantially the same configuration as that of the first embodiment, except for an auxiliary contact hole. The same parts as those of the first embodiment are designated by the same reference signs, and explanation for the same parts may be shortened or omitted.

As shown in FIG. 9 and FIG. 10, in the electroluminescent display device according to the second embodiment of the present disclosure, the first passivation layer 115 can have the first contact hole 115a and an auxiliary contact hole 215b exposing the first auxiliary electrode 172, and the second auxiliary electrode 174 can be in contact with the first auxiliary electrode 172 through the first contact hole 115a and the auxiliary contact hole 215b.

Specifically, the dummy pattern 164 can be provided on the substrate 100, and the buffer layer 111 can be provided on the dummy pattern 164. The gate insulation layer 113 and the first auxiliary electrode 172 can be sequentially provided on the buffer layer 111, and the first passivation layer 115 can be provided on the first auxiliary electrode 172.

The first passivation layer 115 can have the first contact hole 115a and the auxiliary contact hole 215b exposing the top surface of the first auxiliary electrode 172. The auxiliary contact hole 215b can be spaced apart from the first contact hole 115a in the first direction, and the auxiliary contact hole 215b can have a smaller area than the first contact hole 115a.

The second auxiliary electrode 174 can be provided on the first passivation layer 115. The second auxiliary electrode 174 can be in contact with the top surface of the first auxiliary electrode 172 exposed through the first contact hole 115a and the auxiliary contact hole 215b.

The second passivation layer 117 can be provided on the second auxiliary electrode 174. The second passivation layer 117 can have the second contact hole 117a exposing the second auxiliary electrode 174. The second contact hole 117a can have a smaller area than the first contact hole 115a and can be disposed in the first contact hole 115a. The second contact hole 117a can be spaced apart from the auxiliary contact hole 215b.

The overcoat layer 119 can be provided on the second passivation layer 117. The overcoat layer 119 can have a substantially flat top surface and have the third contact hole 119a exposing the second passivation layer 117 and the second auxiliary electrode 174.

The third contact hole 119a can have a smaller area than the first contact hole 115a and can be disposed in the first contact hole 115a. The third contact hole 119a can be spaced apart from the auxiliary contact hole 215b. In addition, the third contact hole 119a can overlap the second contact hole 117a, and the third contact hole 119a can have a wider width than the second contact hole 117a in the first direction and a narrower width than the second contact hole 117a in the second direction.

The light-emitting layer 144 and the second electrode 146 can be sequentially provided on the overcoat layer 119.

As such, in the electroluminescent display device according to the second embodiment of the present disclosure, the second auxiliary electrode 174 can be in contact with the first auxiliary electrode 172 through the first contact hole 115a and the auxiliary contact hole 215b. Accordingly, the contact properties between the first auxiliary electrode 172 and the second auxiliary electrode 174 can be improved in comparison with the first embodiment.

The electroluminescent display device according to the second embodiment of the present disclosure can be manufactured by substantially the same method as the electroluminescent display device according to the first embodiment shown in FIGS. 8A to 8J, and in the step of FIG. 8D, the auxiliary contact hole 215b can be formed together when the first contact hole 115a is formed.

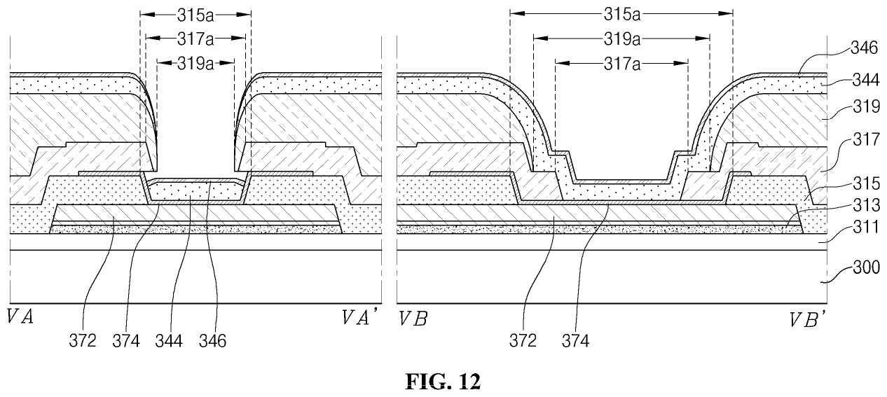

FIG. 11 is a schematic plan view of a contact area of an electroluminescent display device according to a third embodiment of the present disclosure, and FIG. 12 is a cross-sectional view corresponding to the line VA-VA′ and the line VB-VB′ of FIG. 11. The electroluminescent display device according to the third embodiment of the present disclosure has substantially the same configuration as that of the first embodiment, except for the dummy pattern. The same parts as those of the first embodiment are designated by the same or similar reference signs, and explanation for the same parts may be shortened or omitted.

As shown in FIG. 11 and FIG. 12, in the electroluminescent display device according to the third embodiment of the present disclosure, a dummy pattern may not be provided under the first and second auxiliary electrodes 372 and 374, the second auxiliary electrode 374 can have the inclined surface due to the first contact hole 315a of the first passivation layer 315, and the second passivation layer 317, which is an insulation layer on the second auxiliary electrode 374, can have the undercut structure.

Specifically, the buffer layer 311 can be provided on the substrate 300, and the gate insulation layer 313 and the first auxiliary electrode 372 can be sequentially provided on the buffer layer 311. The first auxiliary electrode 372 can have a substantially flat top surface.

The first passivation layer 315 can be provided on the first auxiliary electrode 372. The first passivation layer 315 can have the first contact hole 315a exposing the top surface of the first auxiliary electrode 372. The first passivation layer 315 can have an inclined side surface due to the first contact hole 315a.

The second auxiliary electrode 374 can be provided on the first passivation layer 315. The second auxiliary electrode 374 can have a larger area than the first contact hole 315a and can be in contact with the first auxiliary electrode 372 exposed through the first contact hole 315a. The second auxiliary electrode 374 can have the inclined step surface due to the first contact hole 315a of the first passivation layer 315, and the top surface of the second auxiliary electrode 374 can also have the inclined step surface.

The second passivation layer 317 can be provided on the second auxiliary electrode 374. The second passivation layer 317 can have the second contact hole 317a exposing the second auxiliary electrode 374. The second contact hole 317a can have a smaller area than the first contact hole 315a and can be disposed in the first contact hole 315a.

An undercut structure where the bottom surface of the second passivation layer 317 is exposed can be provided on at least one side of the second contact hole 317a, for example, at upper and lower sides facing each other along the second direction, which is the Y direction, in FIG. 11. The inclined step surface of the second auxiliary electrode 374 can be exposed under the undercut structure.

On the other hand, the undercut structure may not be provided at left and right sides of the second contact hole 317a facing each other along the first direction, which is the X direction, in FIG. 11.

The overcoat layer 319 can be provided on the second passivation layer 317. The overcoat layer 319 can have a substantially flat top surface and have the third contact hole 319a exposing the second passivation layer 317 and the second auxiliary electrode 374.

The third contact hole 319a can have a smaller area than the first contact hole 315a and can be disposed in the first contact hole 315a. In addition, the third contact hole 319a can overlap the second contact hole 317a, and the third contact hole 319a can have a wider width than the second contact hole 317a in the first direction and a narrower width than the second contact hole 317a in the second direction.

Accordingly, the overcoat layer 319 can expose the side and top surfaces of the second passivation layer 317 facing each other in the first direction corresponding to the second contact hole 317a where the undercut structure is not provided. The overcoat layer 319 can cover the side and top surfaces of the second passivation layer 317 facing each other in the second direction corresponding to the second contact hole 317a where the undercut structure is provided. In this case, the bottom surface of the overcoat layer 319 corresponding to the undercut structure can be exposed.

The light-emitting layer 344 and the second electrode 346 can be sequentially provided on the overcoat layer 319. The light-emitting layer 344 and the second electrode 346 can cover the top and side surfaces of the overcoat layer 319. The light-emitting layer 344 and the second electrode 346 can also be disposed on the second passivation layer 317 and the second auxiliary electrode 374 exposed through the third contact hole 319a, and the light-emitting layer 344 can be in contact with the second auxiliary electrode 374 through the third contact hole 319a.

The light-emitting layer 344 and the second electrode 346 in the contact area can be cut off (e.g., disconnected) from the light-emitting layer 344 and the second electrode 346 that extends from the emission area by the undercut structure. Accordingly, the portions of the light-emitting layer 344 and the second electrode 346 over the side surface of the overcoat layer 319 corresponding to the undercut structure can be separated from the portions of the light-emitting layer 344 and the second electrode 346 over the second auxiliary electrode 374. The separated portions of the light-emitting layer 344 and the second electrode 346 can be in contact with the inclined step surface of the second auxiliary electrode 374 under the undercut structure.

On the other hand, the portions of the light-emitting layer 344 and the second electrode 346 over the side surface of the overcoat layer 319 that does not correspond to the undercut structure can be connected to the portions of the light-emitting layer 344 and the second electrode 346 over the second auxiliary electrode 374, respectively, without separation.

Here, the total thickness of the light-emitting layer 344 and the second electrode 346 can be smaller than the thickness of the first passivation layer 315.

As such, in the electroluminescent display device according to the third embodiment of the present disclosure, the dummy pattern may not be provided under the first and second auxiliary electrodes 372 and 374, and the second auxiliary electrode 374 can be configured to have the inclined surface, that is, the inclined step surface due to the structure such as the first contact hole 315a of the first passivation layer 315. In addition, the second passivation layer 317 over the second auxiliary electrode 374 can be configured to have the undercut structure. Accordingly, each of the light-emitting layer 344 and the second electrode 346 over the second passivation layer 317 can be separated by the undercut structure, and the separated second electrode 346 can be in direct contact with the inclined step surface of the second auxiliary electrode 374 under the undercut structure, thereby improving the contact properties between the second electrode 346 and the first and second auxiliary electrodes 372 and 374.

The electroluminescent display device according to the third embodiment of the present disclosure can have a difference in a step of forming the dummy pattern compared to the first embodiment. That is, the electroluminescent display device according to the third embodiment of the present disclosure can be manufactured by substantially the same method as the electroluminescent display device according to the first embodiment shown in FIGS. 8B to 8J, except for the step of forming the dummy pattern.

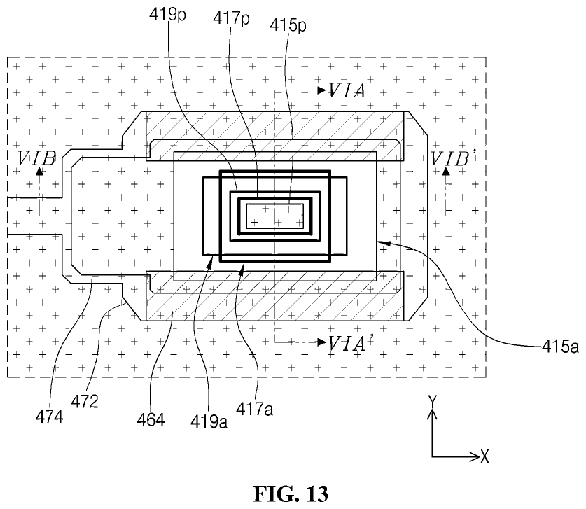

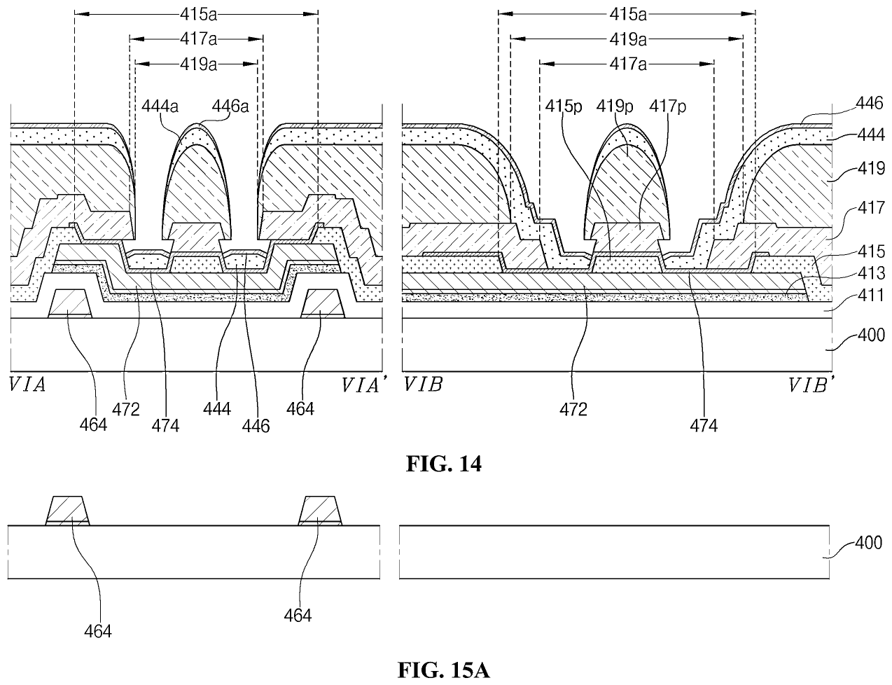

FIG. 13 is a schematic plan view of a contact area of an electroluminescent display device according to a fourth embodiment of the present disclosure, and FIG. 14 is a cross-sectional view corresponding to the line VIA-VIA′ and the line VIB-VIB′ of FIG. 13. The electroluminescent display device according to the fourth embodiment of the present disclosure has substantially the same configuration as that of the first embodiment, except for an island pattern. The same parts as those of the first embodiment are designated by the same or similar reference signs, and explanation for the same parts may be shortened or omitted.

As shown in FIG. 13 and FIG. 14, in the electroluminescent display device according to the fourth embodiment of the present disclosure, by providing the dummy pattern 464 under the first and second auxiliary electrodes 472 and 474, the first and second auxiliary electrodes 472 and 474 can have the inclined surfaces due to the dummy pattern 464, and the second passivation layer 417, which is an insulation layer on the first and second auxiliary electrodes 472 and 474, can have the undercut structure. In addition, first, second, and third island patterns 415p, 417p, 419p can be provided in the first, second, and third contact holes 415a, 417a, 419a, and the second island pattern 417p can have an undercut structure.

Specifically, at least one dummy pattern 464 can be provided on the substrate 400. For example, a couple of dummy patterns 464 can extend in the first direction, which is the X direction, and be spaced apart from each other in the second direction, which is the Y direction.

The buffer layer 411 can be provided on the dummy pattern 464. The buffer layer 411 can have a step difference due to the dummy pattern 464.

The gate insulation layer 413 and the first auxiliary electrode 472 can be sequentially provided on the buffer layer 411. The gate insulation layer 413 and the first auxiliary electrode 472 can overlap the dummy pattern 464 and can have a step difference due to the dummy pattern 464. The first auxiliary electrode 472 can have an inclined step surface due to the step difference corresponding to the dummy pattern 464, and a top surface of the first auxiliary electrode 472 can also have an inclined step surface.

The first passivation layer 415 can be provided on the first auxiliary electrode 472. The first passivation layer 415 can have the first contact hole 415a exposing the top surface of the first auxiliary electrode 472. The first contact hole 415a can expose the inclined step surface of the first auxiliary electrode 472. The first contact hole 415a can overlap the dummy pattern 464.

In addition, the first island pattern 415p can be provided in the first contact hole 415a, and the first island pattern 415p can be formed of the same material as the first passivation layer 415. The first island pattern 415p can be spaced apart from the first passivation layer 415. The first island pattern 415p can overlap the first auxiliary electrode 472 and be disposed between the pair of dummy patterns 464.

The second auxiliary electrode 474 can be provided on the first passivation layer 415 and the first island pattern 415p. The second auxiliary electrode 474 can have a larger area than the first contact hole 415a and be in contact with the first auxiliary electrode 472 exposed through the first contact hole 415a.

The second auxiliary electrode 474 can have the step difference due to the dummy pattern 464. The second auxiliary electrode 474 can have the inclined step surface due to the step difference, and the top surface of the second auxiliary electrode 474 can also have the inclined step surface. The second auxiliary electrode 474 can overlap the dummy pattern 164.

In addition, the second auxiliary electrode 474 can overlap the first island pattern 415p and cover the first island pattern 415p. Accordingly, the second auxiliary electrode 474 can be in contact with the side and top surfaces of the first island pattern 415p, and the first island pattern 415p can be disposed between the first auxiliary electrode 474 and the second auxiliary electrode 474.

The second auxiliary electrode 474 can have a step difference due to the first island pattern 415p. The second auxiliary electrode 474 can have an inclined step surface due to the step difference corresponding to the first island pattern 415p, and the top surface of the second auxiliary electrode 474 can also have an inclined step surface.

The second passivation layer 417 can be provided on the second auxiliary electrode 474. The second passivation layer 417 can have the second contact hole 417a exposing the second auxiliary electrode 474. The second contact hole 417a can have a smaller area than the first contact hole 415a and can be disposed in the first contact hole 415a.

The undercut structure where the bottom surface of the second passivation layer 417 is exposed can be provided on at least one side of the second contact hole 417a, for example, at the upper and lower sides facing each other along the second direction in FIG. 13. The undercut structure can be provided to correspond to the dummy pattern 464. The inclined step surface of the second auxiliary electrode 474 can be exposed through the second contact hole 417a under the undercut structure corresponding to the dummy pattern 464.

On the other hand, the undercut structure may not be provided at the left and right sides of the second contact hole 417a facing each other along the first direction in FIG. 13.

In addition, the second island pattern 417p can be provided in the second contact hole 417a, and the second island pattern 417p can be formed of the same material as the second passivation layer 417. The second island pattern 417p can be disposed over the first island pattern 415a and be spaced apart from the second passivation layer 417. The second island pattern 417p can be in contact with the second auxiliary electrode 474 on the first island pattern 415p.

The second island pattern 417p can include a lower pattern and an upper pattern on the lower pattern. A top width of the lower pattern can be smaller than a bottom width of the upper pattern, and the second island pattern 417p can have an undercut structure in which a bottom surface of the upper pattern is partially exposed. The undercut structure can be provided to correspond to edges of the first island pattern 415p, and the inclined step surface of the second auxiliary electrode 474 can be exposed through the second contact hole 417a under the undercut structure of the second island pattern 417p. That is, the upper pattern extends past an end of the lower pattern and the undercut structure is between the bottom surface of the portion of the upper pattern and the lower pattern.

The overcoat layer 419 can be provided on the second passivation layer 417. The overcoat layer 419 can have a substantially flat top surface and have the third contact hole 419a exposing the second passivation layer 417 and the second auxiliary electrode 474.

The third contact hole 419a can have a smaller area than the first contact hole 415a and be disposed in the first contact hole 415a. In addition, the third contact hole 419a can overlap the second contact hole 417a, and the third contact hole 419a can have a wider width than the second contact hole 417a in the first direction and a narrower width than the second contact hole 417a in the second direction.

Accordingly, the overcoat layer 419 can expose the side and top surfaces of the second passivation layer 417 facing each other in the first direction corresponding to the second contact hole 417a where the undercut structure is not provided. The overcoat layer 419 can cover the side and top surfaces of the second passivation layer 417 facing each other in the second direction corresponding to the second contact hole 417a where the undercut structure is provided. In this case, the bottom surface of the overcoat layer 419 corresponding to the undercut structure can be exposed. That is, a part of the bottom surface of the overcoat layer 419 can be exposed at the upper and lower sides of the third contact hole 419a facing each other along the second direction in FIG. 13.

Meanwhile, the third island pattern 419p can be provided in the third contact hole 419a, and the third island pattern 419p can be formed of the same material as the overcoat layer 419. The third island pattern 419p can be disposed over the second island pattern 417p and be spaced apart from the overcoat layer 419.

The third island pattern 419p can cover a part of the side surface and the top surface of the second island pattern 417p. More particularly, the third island pattern 419p can cover the upper pattern of the second island pattern 417p and expose the lower pattern of the second island pattern 417p. The bottom surface of the third island pattern 419p can be exposed to correspond to the undercut structure of the second island pattern 417p.

The light-emitting layer 444 and the second electrode 446 can be sequentially provided on the overcoat layer 419. The light-emitting layer 444 and the second electrode 446 can cover the top and side surfaces of the overcoat layer 419. The light-emitting layer 444 and the second electrode 446 can also be disposed on the second passivation layer 417 and the second auxiliary electrode 474 exposed through the third contact hole 419a, and the light-emitting layer 444 can be in contact with the second auxiliary electrode 474 through the third contact hole 419a.

The light-emitting layer 444 and the second electrode 446 can be cut off by the undercut structure of the second passivation layer 417. Accordingly, portions of the light-emitting layer 444 and the second electrode 446 over the side surface of the overcoat layer 419 corresponding to the undercut structure can be separated from portions of the light-emitting layer 444 and the second electrode 446 over the second auxiliary electrode 474, respectively. The separated portions of the light-emitting layer 444 and the second electrode 446 can be in contact with the inclined step surface of the second auxiliary electrode 474 under the undercut structure of the second passivation layer 417.

On the other hand, portions of the light-emitting layer 444 and the second electrode 446 over the side surface of the overcoat layer 419 that does not correspond to the undercut structure can be connected to the portions of the light-emitting layer 444 and the second electrode 446 over the second auxiliary electrode 474, respectively, without separation.

Meanwhile, a dummy light-emitting layer 444a and a dummy electrode pattern 446a can be provided on the third island pattern 419a. The dummy light-emitting layer 444a and the dummy electrode pattern 446a can be cut off by the undercut structure of the second island pattern 417p. Accordingly, the dummy light-emitting layer 444a and the dummy electrode pattern 446a on the third island pattern 419p can be separated from the portions of the light-emitting layer 444 and the second electrode 446 over the second auxiliary electrode 474. The separated portions of the light-emitting layer 444 and the second electrode 446 can be in contact with the inclined step surface of the second auxiliary electrode 474 on the first island pattern 415p under the undercut structure of the second island pattern 417p.

In this case, the total thickness of the light-emitting layer 444 and the second electrode 446 can be smaller than the thickness of the first passivation layer 415.

As such, in the electroluminescent display device according to the fourth embodiment of the present disclosure, the structure such as the dummy pattern 464 can be provided under the first and second auxiliary electrodes 472 and 474, so that the first and second auxiliary electrodes 472 and 474 can be configured to have the inclined surface, that is, the inclined step surface due to the step difference of the dummy pattern 464. The second passivation layer 417 over the first and second auxiliary electrodes 472 and 474 can be configured to have the undercut structure. In addition, by further providing the structure such as the first island pattern 415p, the second auxiliary electrode 474 can also be configured to have the inclined step surface, and the second island pattern 417p on the second auxiliary electrode 474 can also be configured to have the undercut structure.

Accordingly, each of the light-emitting layer 444 and the second electrode 446 over the second passivation layer 417 and the second island pattern 417p can be separated by the undercut structures, and the separated second electrode 446 can be in direct contact with the inclined step surface of the second auxiliary electrode 474 under the undercut structures, thereby increasing the contact area between the second electrode 446 and the second auxiliary electrode 474 compared to the first embodiment and further improving the contact properties between the second electrode 446 and the first and second auxiliary electrodes 472 and 474.

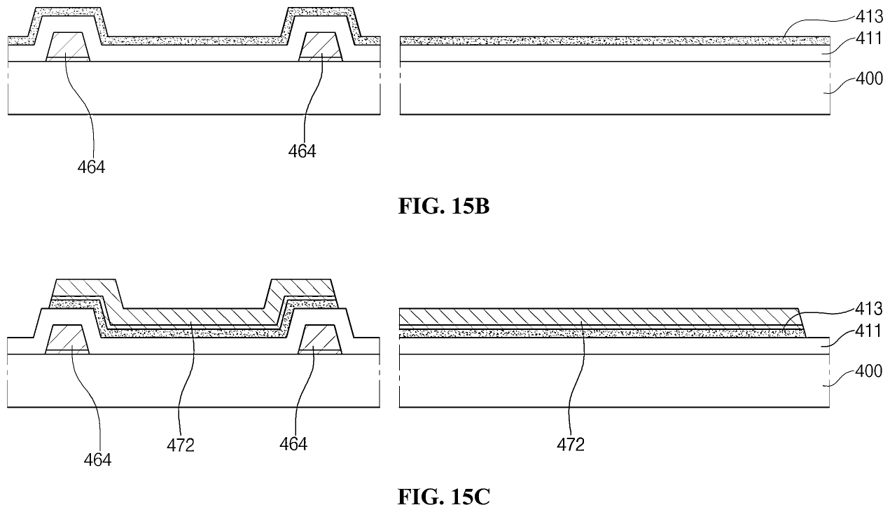

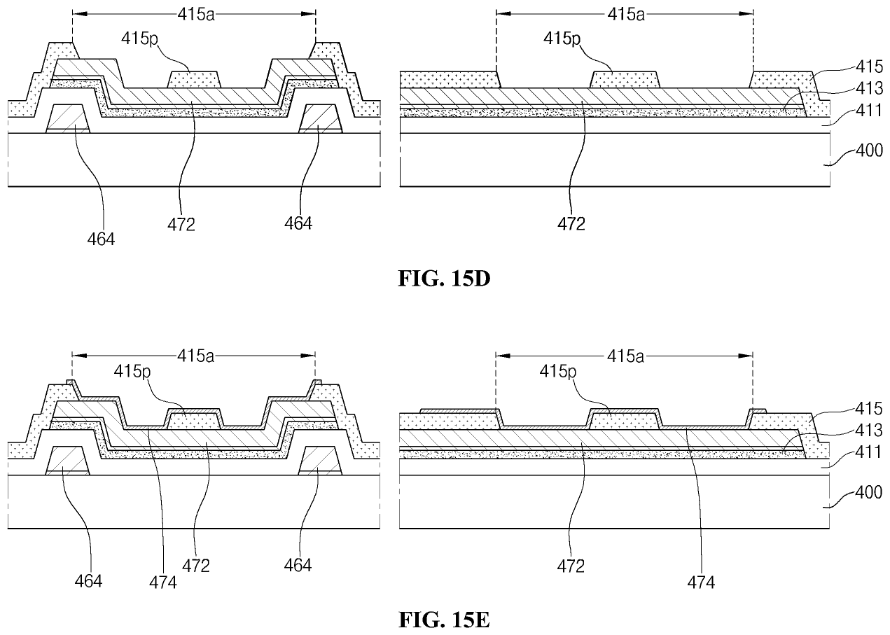

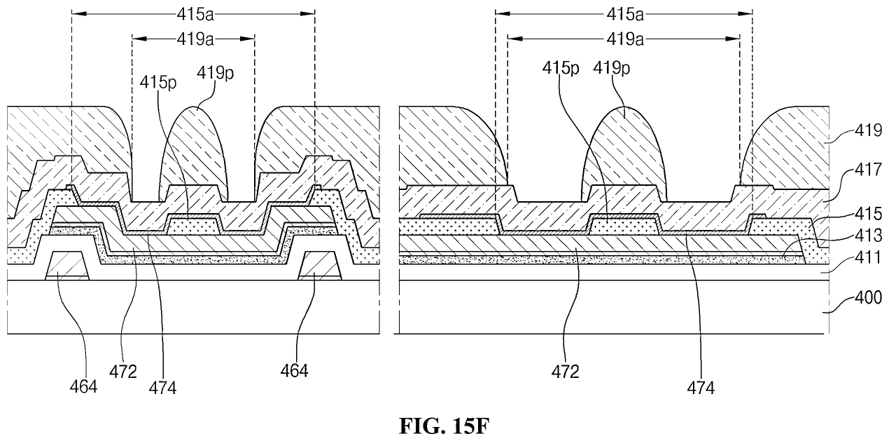

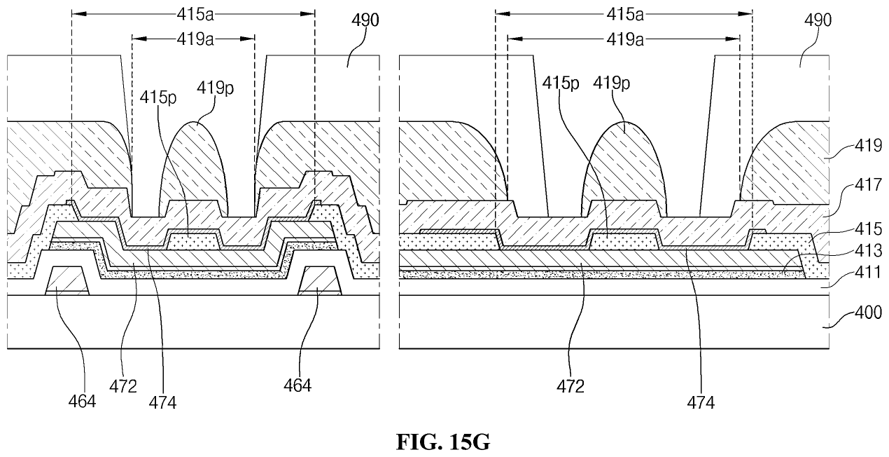

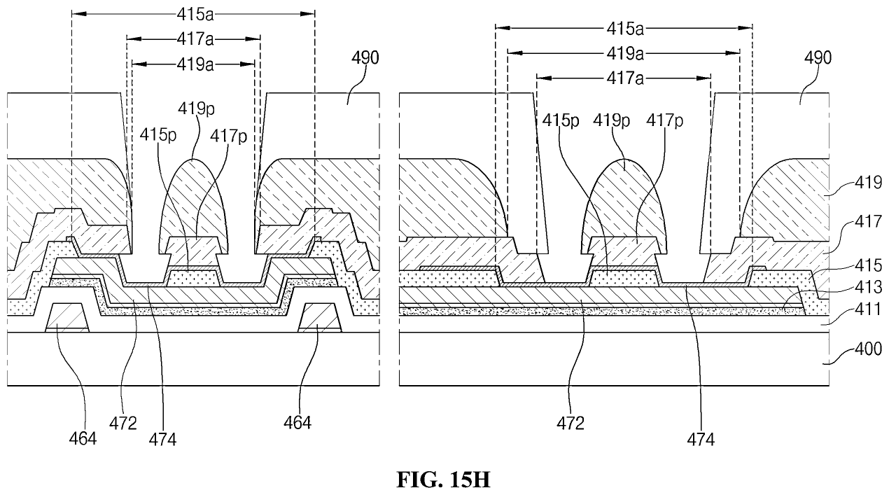

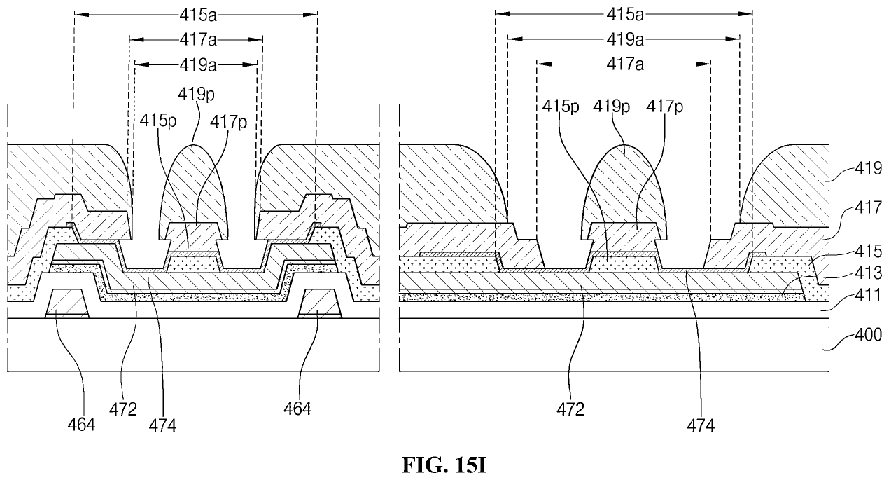

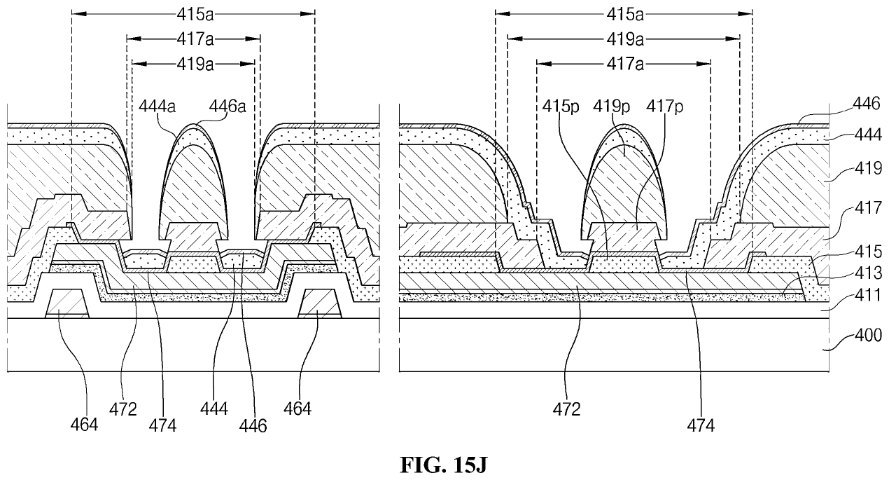

A method of manufacturing the electroluminescent display device according to the fourth embodiment of the present disclosure will be described in detail with reference to FIGS. 15A to 15J.

FIGS. 15A to 15J are schematic cross-sectional views of a contact area in steps of manufacturing an electroluminescent display device according to the fourth embodiment of the present disclosure. The method of manufacturing the electroluminescent display device according to the fourth embodiment of the present disclosure includes substantially the same steps as those of the first embodiment, except for the steps of forming the island patterns. The same parts as those of the first embodiment are designated by the same reference signs, and explanation for the same parts may be shortened or omitted.

First, in FIG. 15A, the dummy pattern 464 can be formed on the substrate 400 by depositing a conductive material and patterning it through a photolithography process.

Next, in FIG. 15B, the buffer layer 411 can be formed on the dummy pattern 464 by depositing an inorganic insulating material over substantially the entire surface of the substrate 400. The gate insulation layer 413 can be formed on the buffer layer 411 by depositing an inorganic insulating material over substantially the entire surface of the substrate 400.

Next, in FIG. 15C, the first auxiliary electrode 472 can be formed on the gate insulation layer 413 by depositing a conductive material and patterning it through a photolithography process. At this time, the gate insulation layer 413 can also be patterned to have the same shape as the first auxiliary electrode 472.

Next, in FIG. 15D, the first passivation layer 415 can be formed on the first auxiliary electrode 472 by depositing an inorganic insulating material, and then the first passivation layer 415 can be patterned through a photolithography process, thereby forming the first contact hole 415a and the first island pattern 415p. The first contact hole 415a can expose the first auxiliary electrode 415, and the first island pattern 415p can be disposed in the first contact hole 415a.

Next, in FIG. 15E, the second auxiliary electrode 474 can be formed on the first passivation layer 415 and the first island pattern 415p by depositing a conductive material and patterning it through a photolithography process.

The second auxiliary electrode 474 can overlap the first auxiliary electrode 472 and be in contact with the first auxiliary electrode 472 through the first contact hole 415a. In addition, the second auxiliary electrode 474 can overlap and cover the first island pattern 415p and be in contact with the side and top surfaces of the first island pattern 415p.

Next, in FIG. 15F, the second passivation layer 417 can be formed on the second auxiliary electrode 474 by depositing an inorganic insulating material, and the overcoat layer 419 can be formed on the second passivation layer 417 by applying an organic insulating material. Then, the overcoat layer 419 can be patterned through a photolithography process, thereby forming the third contact hole 419a and the third island pattern 419p. The third contact hole 419a can expose the second passivation layer 417, and the third island pattern 419p can be disposed in the third contact hole 419a.

The overcoat layer 419 can be formed of a material having negative photosensitivity in which a portion exposed to light remains after developing. However, embodiments of the present disclosure are not limited thereto. In other embodiments, the overcoat layer 419 can be formed of a material having positive photosensitivity in which a portion exposed to light is removed after developing.

Next, in FIG. 15G, photoresist can be applied on the overcoat layer 419 and the third island pattern 419p, be exposed to light, and be developed, thereby forming a photoresist pattern 490 exposing the second passivation layer 417.

In an area where the dummy pattern 464 is provided, edges of the photoresist pattern 490 can be disposed on the overcoat layer 419, and the photoresist pattern 490 can expose the side surface or the top and side surfaces of the overcoat layer 419. On the other hand, in an area where the dummy pattern 464 is not provided, edges of the photoresist pattern 490 can be disposed on the second passivation layer 417, and the photoresist pattern 490 can cover the top and side surfaces of the overcoat layer 419. In addition, the photoresist pattern 490 may not be provided on the third island pattern 419p.

Next, in FIG. 15H, the second contact hole 417a and the second island pattern 417p can be formed by selectively removing the exposed second passivation layer 417 using the photoresist pattern 490 as an etch mask. Here, the second passivation layer 417 can be removed through a wet etching process.

In the area where the dummy pattern 464 is provided, the second passivation layer 417 under the overcoat layer 419 can be over-etched, and the width of the second contact hole 417a can be greater than the width of the third contact hole 419a, thereby forming the undercut structure where the bottom surface of the overcoat layer 419 and the bottom surface of the second passivation layer 417 are exposed. On the other hand, in the area where the dummy pattern 464 is not provided, even though the second passivation layer 417 under the photoresist pattern 490 is over-etched, the width of the second contact hole 417a can be smaller than the width of the third contact hole 419a, so that the undercut structure may not be formed.

In addition, the second passivation layer 417 under the third island pattern 419p can be over-etched, so that the second island pattern 417p can include the lower pattern and the upper pattern and the undercut structure in which the bottom surface of the third island pattern 419p and the bottom surface of the upper pattern of the second passivation layer 417 can be formed.

Next, in FIG. 15I, the photoresist pattern 490 of FIG. 15H can be stripped and removed.

Next, in FIG. 15J, the light-emitting layer 444 and the second electrode 446 can be sequentially formed on the overcoat layer 419. The light-emitting layer 444 and the second electrode 446 can be separated by the undercut structures of the second passivation layer 417 and the second island pattern 417p, and the separated portions of the light-emitting layer 444 and the second electrode 446 can be in contact with the inclined step surface of the second auxiliary electrode 474 under the undercut structures.

As such, in the method of manufacturing the electroluminescent display device according to the fourth embodiment of the present disclosure, the first, second, and third island patterns 415p, 417p, and 419p can be formed when the first, second, and third contact holes 415a, 417a, and 419a, respectively. After the third contact hole 419a of the overcoat layer 419 and the third island pattern 419p are formed, the second contact hole 417a of the second passivation layer 417 and the second island pattern 417p can be formed. Accordingly, the contact area between the second electrode 446 and the second auxiliary electrode 474 can be increased without increasing a process compared to the first embodiment.

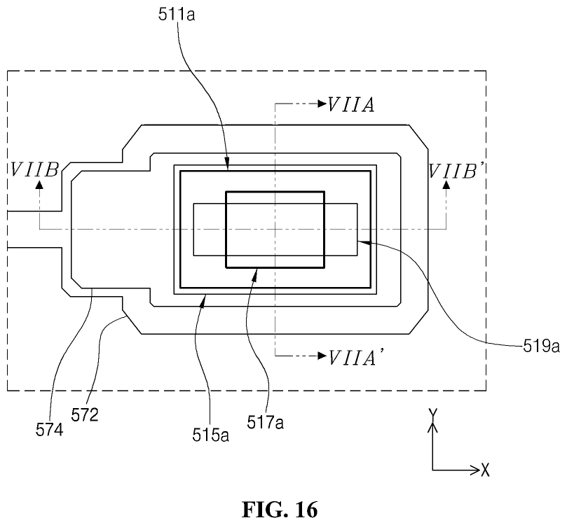

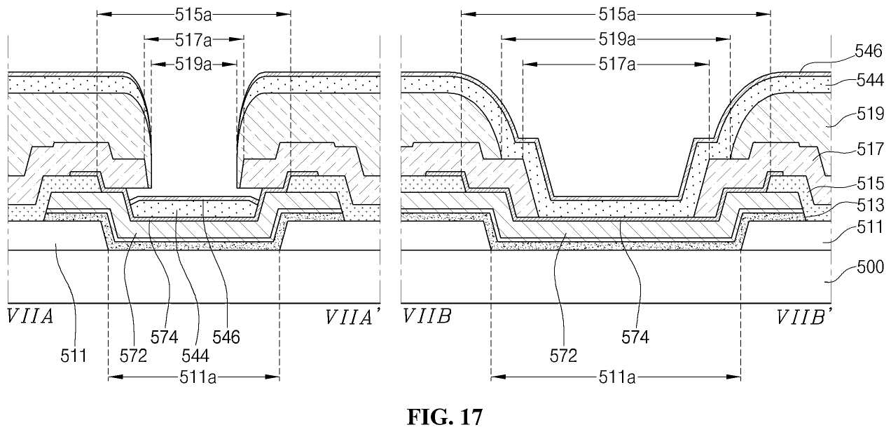

FIG. 16 is a schematic plan view of a contact area of an electroluminescent display device according to a fifth embodiment of the present disclosure, and FIG. 17 is a cross-sectional view corresponding to the line VIIA-VIIA′ and the line VIIB-VIIB′ of FIG. 16 according to one embodiment of the present disclosure. The electroluminescent display device according to the fifth embodiment of the present disclosure has substantially the same configuration as that of the first embodiment, except for the dummy pattern and an opening. The same parts as those of the first embodiment are designated by the same or similar reference signs, and explanation for the same parts may be shortened or omitted.

As shown in FIG. 16 and FIG. 17, in the electroluminescent display device according to the fifth embodiment of the present disclosure, a dummy pattern may not be provided under the first and second auxiliary electrodes 572 and 574. By providing an opening 511a in the buffer layer 511, the first and second auxiliary electrodes 572 and 574 can have the inclined surfaces due to the opening 511a, and the second passivation layer 517, which is an insulation layer on the first and second auxiliary electrodes 572 and 574, can have the undercut structure.

Specifically, the buffer layer 511 can be provided on the substrate 500. The buffer layer 511 can have the opening 511a exposing the substrate 500.

The gate insulation layer 513 and the first auxiliary electrode 572 can be sequentially provided on the buffer layer 511. The gate insulation layer 513 and the first auxiliary electrode 572 can have a larger area than the opening 511a. The gate insulation layer 513 can be in contact with top and side surfaces of the buffer layer 511 and also be in contact with the substrate 500 exposed through the opening 511a.

The gate insulation layer 513 and the first auxiliary electrode 572 can have step differences due to the opening 511a. The first auxiliary electrode 572 can have the inclined step surface due to the step difference corresponding to the opening 511a, and the top surface of the first auxiliary electrode 572 can also have the inclined step surface.

The first passivation layer 515 can be provided on the first auxiliary electrode 572. The first passivation layer 515 can have the first contact hole 515a exposing the top surface of the first auxiliary electrode 572. The first contact hole 515a can have a larger area than the opening 511a, and the opening 511a can be disposed in the first contact hole 515a. The first contact hole 515a can expose the inclined step surface of the first auxiliary electrode 572.

The second auxiliary electrode 574 can be provided on the first passivation layer 515. The second auxiliary electrode 574 can have a larger area than the first contact hole 515a and the opening 511a and can be in contact with the first auxiliary electrode 572 exposed through the first contact hole 515a.

The second auxiliary electrode 574 can have a step difference due to the opening 511a. The second auxiliary electrode 574 can have the inclined step surface due to the step difference corresponding to the opening 511a, and the top surface of the second auxiliary electrode 574 can also have the inclined step surface.

The second passivation layer 517 can be provided on the second auxiliary electrode 574. The second passivation layer 517 can have the second contact hole 517a exposing the second auxiliary electrode 574. The second contact hole 517a can have a smaller area than the first contact hole 515a and can be disposed in the first contact hole 515a. In addition, the second contact hole 517a can have a smaller area than the opening 511a and can be disposed in the opening 511a.

The undercut structure where the bottom surface of the second passivation layer 517 is exposed can be provided on at least one side of the second contact hole 517a, for example, at the upper and lower sides facing each other along the second direction, which is the Y direction, in FIG. 16. The undercut structure can correspond to the opening 511a. The inclined step surface of the second auxiliary electrode 574 can be exposed through the second contact hole 517a under the undercut structure corresponding to the opening 511a.

On the other hand, the undercut structure may not be provided at the left and right sides of the second contact hole 517a facing each other along the first direction, which is the X direction, in FIG. 13.

The overcoat layer 519 can be provided on the second passivation layer 517. The overcoat layer 519 can have a substantially flat top surface and have the third contact hole 519a exposing the second passivation layer 517 and the second auxiliary electrode 574.

The third contact hole 519a can have a smaller area than the first contact hole 515a and the opening 511a and be disposed in the first contact hole 515a and the opening 511a. In addition, the third contact hole 519a can overlap the second contact hole 517a, and the third contact hole 519a can have a wider width than the second contact hole 517a in the first direction and a narrower width than the second contact hole 517a in the second direction.

Accordingly, the overcoat layer 619 can expose the side and top surfaces of the second passivation layer 517 facing each other in the first direction corresponding to the second contact hole 517a where the undercut structure is not provided. The overcoat layer 519 can cover the side and top surfaces of the second passivation layer 517 facing each other in the second direction corresponding to the second contact hole 517a where the undercut structure is provided. In this case, the bottom surface of the overcoat layer 519 corresponding to the undercut structure can be exposed.

The light-emitting layer 544 and the second electrode 546 can be sequentially provided on the overcoat layer 519. The light-emitting layer 544 and the second electrode 546 can cover the top and side surfaces of the overcoat layer 519. The light-emitting layer 544 and the second electrode 546 can also be disposed on the second passivation layer 517 and the second auxiliary electrode 574 exposed through the third contact hole 519a, and the light-emitting layer 544 can be in contact with the second auxiliary electrode 574 through the third contact hole 519a.

The light-emitting layer 544 and the second electrode 546 can be cut off by the undercut structure. Accordingly, the portions of the light-emitting layer 544 and the second electrode 546 over the side surface of the overcoat layer 519 corresponding to the undercut structure can be separated from the portions of the light-emitting layer 544 and the second electrode 546 over the second auxiliary electrode 574, respectively. The separated portions of the light-emitting layer 544 and the second electrode 546 can be in contact with the inclined step surface of the second auxiliary electrode 574 under the undercut structure.

On the other hand, the portions of the light-emitting layer 544 and the second electrode 546 over the side surface of the overcoat layer 519 that does not correspond to the undercut structure can be connected to the portions of the light-emitting layer 544 and the second electrode 546 over the second auxiliary electrode 574, respectively, without separation.

As such, in the electroluminescent display device according to the fifth embodiment of the present disclosure, the structure such as the opening 511a can be provided in the buffer layer 511 under the first and second auxiliary electrodes 572 and 574, so that the first and second auxiliary electrodes 572 and 574 can be configured to have the inclined surface, that is, the inclined step surface due to the opening 511a thereby resulting in the inclined surface being in the opening 511a The second passivation layer 517 over the first and second auxiliary electrodes 572 and 574 can be configured to have the undercut structure. Accordingly, each of the light-emitting layer 544 and the second electrode 546 over the second passivation layer 517 can be separated by the undercut structure, and the separated second electrode 546 can be in direct contact with the inclined step surface of the first or second auxiliary electrode 572 or 574 under the undercut structure, thereby improving the contact properties between the second electrode 546 and the first and second auxiliary electrodes 572 and 574.

The electroluminescent display device according to the fifth embodiment of the present disclosure can have a difference in steps of forming the dummy pattern and forming the buffer layer compared to the first embodiment. That is, the electroluminescent display device according to the fifth embodiment of the present disclosure can be manufactured by substantially the same method as the electroluminescent display device according to the first embodiment shown in FIGS. 8B to 8J, except for the step of forming the dummy pattern, and in the step of FIG. 8B, the opening 511a can be formed in the buffer layer 511. In this case, the opening 511a can also be formed in the gate insulation layer 513.

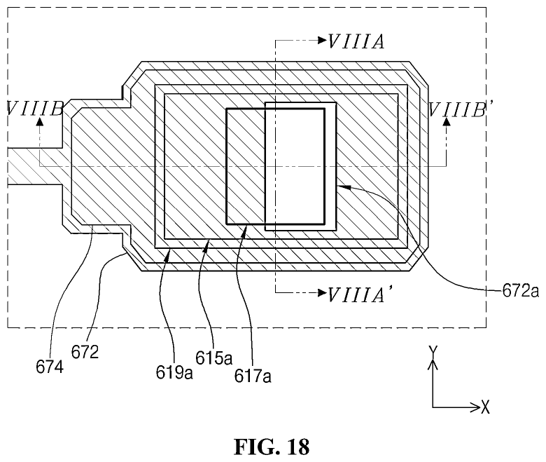

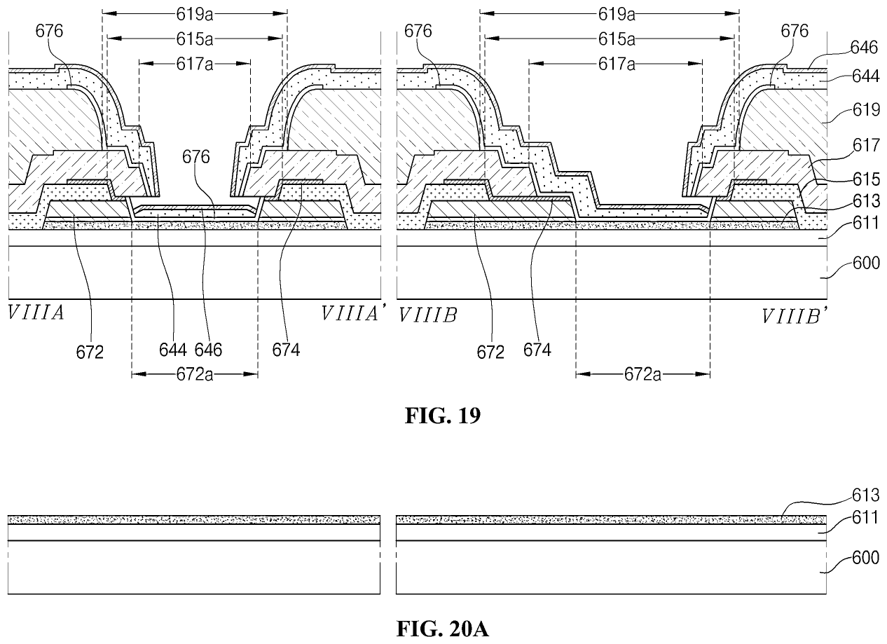

FIG. 18 is a schematic plan view of a contact area of an electroluminescent display device according to a sixth embodiment of the present disclosure, and FIG. 19 is a cross-sectional view corresponding to the line VIIIA-VIIIA′ and the line VIIIB-VIIIB′ of FIG. 18. The electroluminescent display device according to the sixth embodiment of the present disclosure has substantially the same configuration as that of the first embodiment, except for the dummy pattern, an opening, and a third auxiliary electrode. The same parts as those of the first embodiment are designated by the same or similar reference signs, and explanation for the same parts may be shortened or omitted.

As shown in FIG. 18 and FIG. 19, in the electroluminescent display device according to the sixth embodiment of the present disclosure, a dummy pattern may not be provided under the first and second auxiliary electrodes 672 and 674. By providing an opening 672a in the first and second auxiliary electrodes 672 and 674, the first and second auxiliary electrodes 672 and 674 can have the inclined surfaces due to the opening 672a, and the second passivation layer 617, which is an insulation layer on the first and second auxiliary electrodes 672 and 674, can have the undercut structure. In this case, a third auxiliary electrode 676 can be provided in the opening 672a and cover the inclined surfaces of the first and second auxiliary electrodes 672 and 674.

Specifically, the buffer layer 611 can be provided on the substrate 600. The gate insulation layer 613 and the first auxiliary electrode 672 can be sequentially provided on the buffer layer 611.

The first auxiliary electrode 672 can have an opening 672a, and the gate insulation layer 613 can be exposed through the opening 672a. The first auxiliary electrode 672 can have an inclined surface, that is, an inclined side surface due to the opening 672a.

The first passivation layer 615 can be provided on the first auxiliary electrode 672. The first passivation layer 615 can have the first contact hole 615a exposing the top surface of the first auxiliary electrode 672. The first contact hole 615a can have a larger area than the opening 672a, and the opening 672a can be disposed in the first contact hole 615a. The first contact hole 615a can expose the inclined side surface of the first auxiliary electrode 672.

The second auxiliary electrode 674 can be provided on the first passivation layer 615. The second auxiliary electrode 674 can have a substantially larger area than the first contact hole 615a and the opening 672a and can be in contact with the first auxiliary electrode 672 exposed through the first contact hole 615a. The opening 672a can extend in the second auxiliary electrode 674, and the second auxiliary electrode 674 can have the inclined surface, that is, the inclined side surface due to the opening 672a.

The second passivation layer 617 can be provided on the second auxiliary electrode 674. The second passivation layer 617 can have the second contact hole 617a exposing the second auxiliary electrode 674. The second contact hole 617a can have a smaller area than the first contact hole 615a and can be disposed in the first contact hole 615a. In addition, the second contact hole 617a can partially overlap the opening 672a in the first direction, which is the X direction and have a smaller width than the opening 672a in the second direction, which is the Y direction.

Accordingly, in an area where an edge of the opening 672a is not disposed in the second contact hole 617a and is disposed under the second passivation layer 617, an undercut structure in which the bottom surface of the second passivation layer 617 is exposed can be provided. That is, the undercut structure can be provided in the area where an edge of the second contact hole 617a is disposed in the opening 672a. The inclined side surfaces of the first and second auxiliary electrodes 672 and 674 can be substantially exposed under the undercut structure.

On the other hand, in an area where the edge of the opening 672a is disposed in the second contact hole 617a, the undercut structure may not be provided, and the top and side surfaces of the second auxiliary electrode 674 and the side surface of the first auxiliary electrode 672 can be exposed through the second contact hole 617a. That is, the undercut structure may not be provided in the area where the edge of the second contact hole 617a is not disposed in the opening 672a and is disposed over the first and second auxiliary electrodes 672 and 674.

The overcoat layer 619 can be provided on the second passivation layer 617. The overcoat layer 619 can have a substantially flat top surface and have the third contact hole 619a exposing the second passivation layer 617 and the second auxiliary electrode 674.

The third contact hole 619a can have a larger area than the first contact hole 615a, the second contact hole 617a, and the opening 672a, and the first contact hole 615a, the second contact hole 617a, and the opening 672a can be disposed in the third contact hole 619a. However, embodiments of the present disclosure are not limited thereto. In other embodiments, the third contact hole 619a can have a smaller area than the first contact hole 615a and be disposed in the first contact hole 615a.

The third auxiliary electrode 676 can be provided on the overcoat layer 619. The third auxiliary electrode 676 can have substantially the same area as the second auxiliary electrode 674. The third auxiliary electrode 676 can be in contact with the top and side surfaces of the overcoat layer 619 and be in contact with the top and side surfaces of the second passivation layer 617 exposed through the third contact hole 619a.

In addition, the third auxiliary electrode 676 can be in contact with the top surface of the second auxiliary electrode 674 exposed through the second contact hole 617a. The third auxiliary electrode 676 can also be provided in the opening 672a and be in contact with the side surfaces of the first and second auxiliary electrodes 672 and 674 and the top surface of the gate insulation layer 613 exposed through the opening 672a. Accordingly, the third auxiliary electrode 676 can have an inclined surface due to the opening 672a.

The third auxiliary electrode 676 can cover the exposed side surface of the first auxiliary electrode 672 to thereby prevent oxidation and/or damages of the first auxiliary electrode 672. The third auxiliary electrode 676 can be formed of indium tin oxide (ITO) or an alloy of molybdenum and titanium (MoTi), but embodiments of the present disclosure are not limited thereto.

The third auxiliary electrode 676 can be cut off by the undercut structure. A portion of the third auxiliary electrode 676 on the second passivation layer 617 corresponding to the undercut structure can be separated from a portion of the third auxiliary electrode 676 on the gate insulation layer 613. Alternatively, in other embodiments, the third auxiliary electrode 676 can be provided on the bottom surface of the second passivation layer 617 corresponding to the undercut structure to thereby be connected without separation.

The light-emitting layer 644 and the second electrode 646 can be sequentially provided on the third auxiliary electrode 676 and the overcoat layer 619. The light-emitting layer 644 and the second electrode 646 can cover the overcoat layer 619 and the third auxiliary electrode 676.

The light-emitting layer 644 and the second electrode 646 can be cut off by the undercut structure. Accordingly, the portions of the light-emitting layer 644 and the second electrode 646 over the second passivation layer 617 corresponding to the undercut structure can be separated from the portions of the light-emitting layer 644 and the second electrode 646 over the gate insulation layer 613 in the opening 672a, respectively. The separated portions of the light-emitting layer 644 and the second electrode 646 can be in contact with the inclined surface of the third auxiliary electrode 676 under the undercut structure.

On the other hand, the portions of the light-emitting layer 644 and the second electrode 646 over the second passivation layer 617 that does not correspond to the undercut structure can be connected to the portions of the light-emitting layer 644 and the second electrode 646 over the gate insulation layer 613 in the opening 672a, respectively, without separation.

Here, the total thickness of the light-emitting layer 644 and the second electrode 646 can be smaller than the total thickness of the first and second auxiliary electrodes 672 and 674.

As such, in the electroluminescent display device according to the sixth embodiment of the present disclosure, the structure such as the opening 672a can be provided in the first and second auxiliary electrodes 672 and 674, so that the first and second auxiliary electrodes 672 and 674 can have the inclined surface, that is, the inclined side surface due to the opening 672a. The third auxiliary electrode 676 covering the opening 672a can be configured to have the inclined surface, and the second passivation layer 617 over the first and second auxiliary electrodes 672 and 674 can be configured to have the undercut structure. Accordingly, each of the light-emitting layer 644 and the second electrode 646 over the second passivation layer 617 can be separated by the undercut structure, and the separated second electrode 646 can be in direct contact with the inclined surface of the third auxiliary electrode 676 under the undercut structure, thereby improving the contact properties between the second electrode 646 and the first, second, and third auxiliary electrodes 672, 674, and 676.

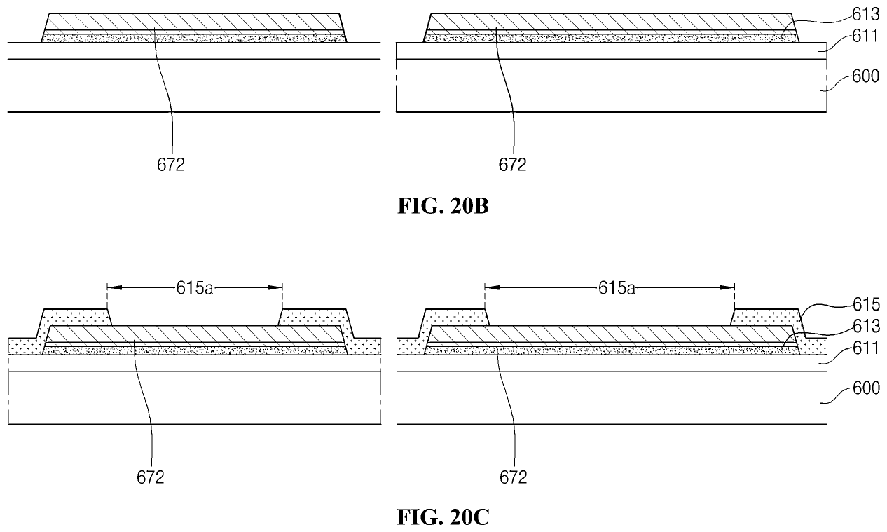

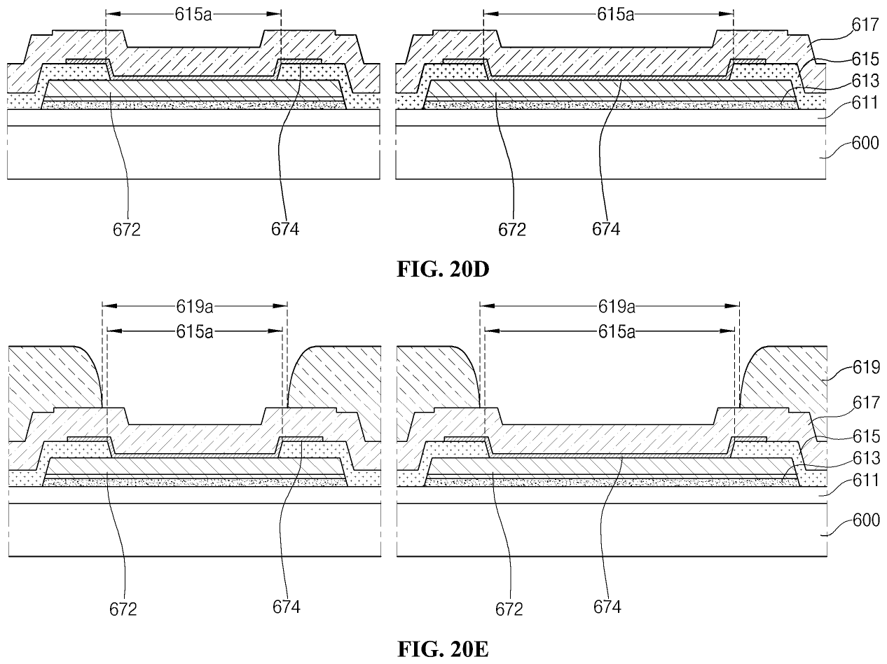

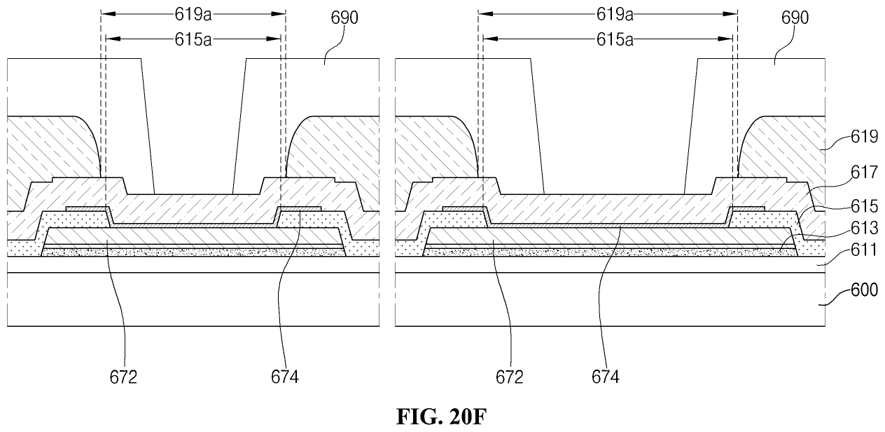

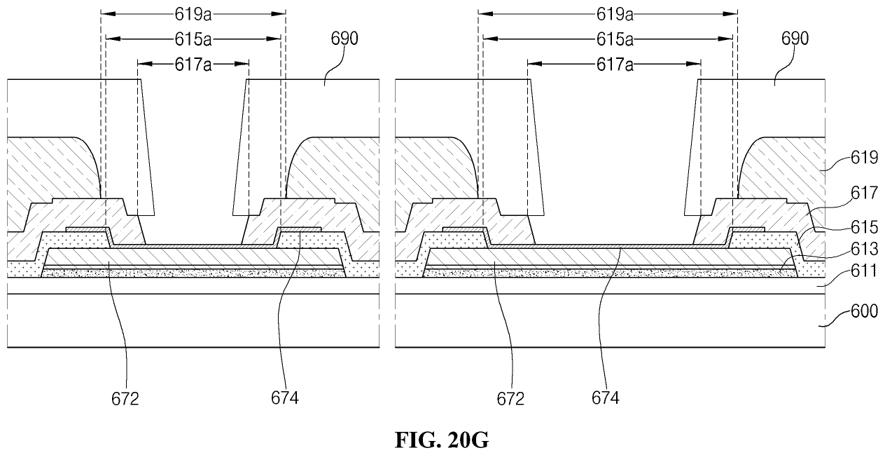

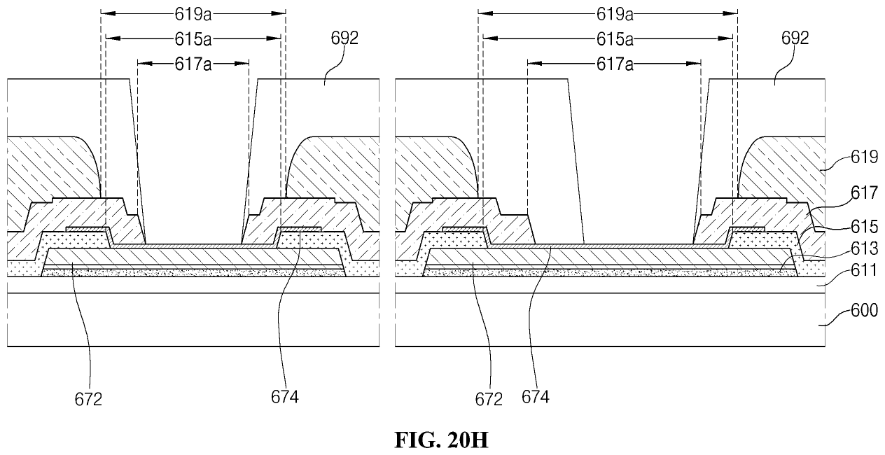

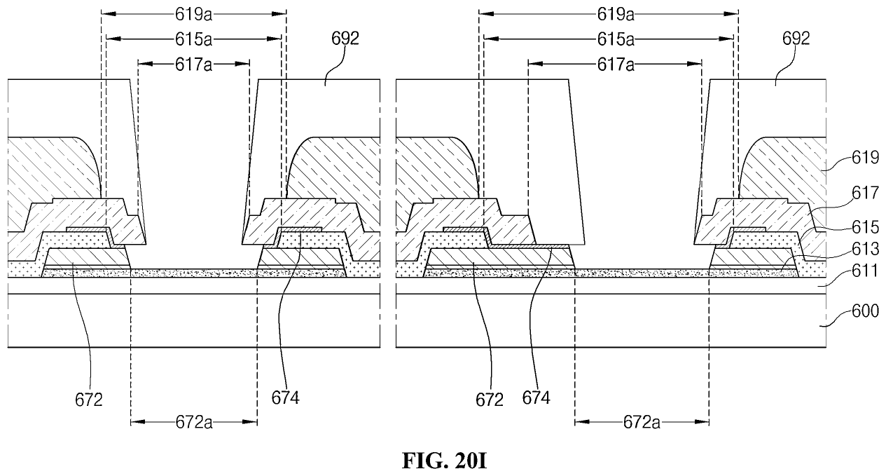

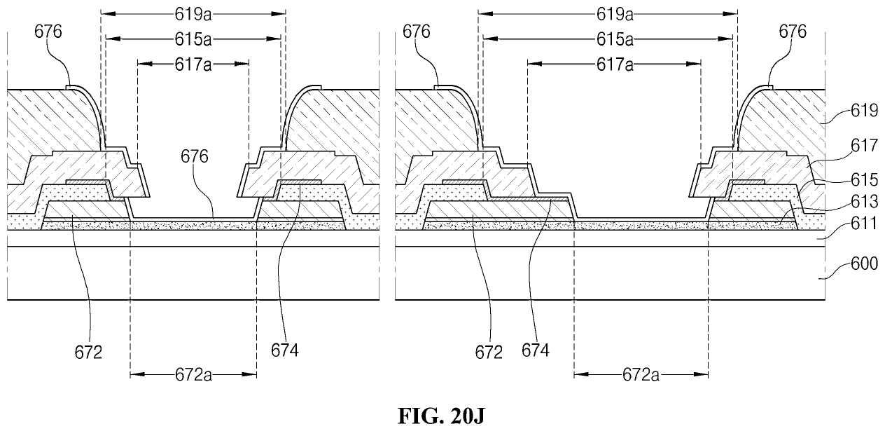

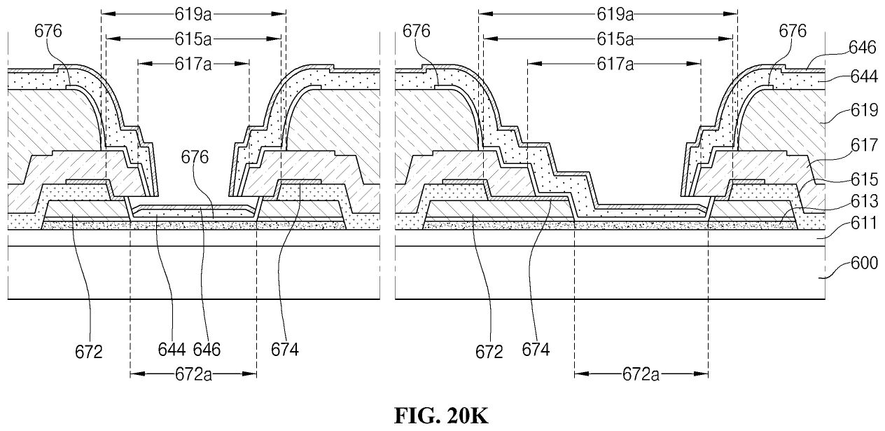

A method of manufacturing the electroluminescent display device according to the sixth embodiment of the present disclosure will be described in detail with reference to FIGS. 20A to 20K.

FIGS. 20A to 20K are schematic cross-sectional views of a contact area in steps of manufacturing an electroluminescent display device according to the sixth embodiment of the present disclosure. The method of manufacturing the electroluminescent display device according to the sixth embodiment of the present disclosure includes substantially the same steps as those of the first embodiment, except for the steps of forming the dummy pattern, the opening, and the third auxiliary electrode. The same parts as those of the first embodiment are designated by the same reference signs, and explanation for the same parts may be shortened or omitted.

In FIG. 20A, the buffer layer 611 can be formed on the substrate 600 by depositing an inorganic insulating material over substantially the entire surface of the substrate 600. The gate insulation layer 613 can be formed on the buffer layer 611 by depositing an inorganic insulating material over substantially the entire surface of the substrate 600.

Next, in FIG. 20B, the first auxiliary electrode 672 can be formed on the gate insulation layer 613 by depositing a conductive material and patterning it through a photolithography process. At this time, the gate insulation layer 613 can also be patterned to have the same shape as the first auxiliary electrode 672.

Next, in FIG. 20C, the first passivation layer 615 can be formed on the first auxiliary electrode 672 by depositing an inorganic insulating material, and then the first passivation layer 615 can be patterned through a photolithography process, thereby forming the first contact hole 615a exposing the first auxiliary electrode 615.

Next, in FIG. 20D, the second auxiliary electrode 674 can be formed on the first passivation layer 615 by depositing a conductive material and patterning it through a photolithography process. Then, the second passivation layer 617 can be formed on the second auxiliary electrode 674 by depositing an inorganic insulating material.

The second auxiliary electrode 674 can overlap the first auxiliary electrode 672 and be in contact with the first auxiliary electrode 672 through the first contact hole 615a.

Next, in FIG. 20E, the overcoat layer 619 can be formed on the second passivation layer 617 by applying an organic insulating material. Then, the overcoat layer 619 can be patterned through a photolithography process, thereby forming the third contact hole 619a exposing the second passivation layer 617.

The overcoat layer 619 can be formed of a material having negative photosensitivity in which a portion exposed to light remains after developing. However, embodiments of the present disclosure are not limited thereto. In other embodiments, the overcoat layer 619 can be formed of a material having positive photosensitivity in which a portion exposed to light is removed after developing.

Next, in FIG. 20F, photoresist can be applied on the overcoat layer 619, be exposed to light, and be developed, thereby forming a first photoresist pattern 690 exposing the second passivation layer 617. Edges of the first photoresist pattern 690 can be disposed on the second passivation layer 617 in the third contact hole 619a, and the first photoresist pattern 690 can cover the top and side surfaces of the overcoat layer 619.

Next, in FIG. 20G, the second contact hole 617a can be formed by selectively removing the exposed second passivation layer 617 using the first photoresist pattern 690 as an etch mask. The second contact hole 617a can expose the second auxiliary electrode 674. Here, the second passivation layer 617 can be removed through a wet etching process and can be over-etched under the first photoresist pattern 690.

The second contact hole 617a can have the smaller area than the first and third contact holes 615a and 619a and can be disposed in the first and third contact holes 615a and 619a.

Then, the first photoresist pattern 690 can be stripped and removed.

Next, in FIG. 20H, photoresist can be applied on the second passivation layer 617 with the second contact hole 617a and the overcoat layer 619, be exposed to light, and be developed, thereby forming a second photoresist pattern 692 exposing the second auxiliary electrode 674.

Edges of the second photoresist pattern 692 can be disposed on the second passivation layer 617, and at least one edge of the second photoresist pattern 692 can be disposed on the second auxiliary electrode 674. Accordingly, the second photoresist pattern 692 can cover the top and side surfaces of the overcoat layer 619 and the top and side surfaces of the second passivation layer 617, and the at least one edge of the second photoresist pattern 692 can be disposed in the second contact hole 617a and be spaced apart from the second contact hole 617a.

Next, in FIG. 20I, the opening 672a can be formed by selectively removing the exposed second auxiliary electrode 674 and the first auxiliary electrode 672 thereunder using the second photoresist pattern 692 as an etch mask. The opening 672a can expose the gate insulation layer 613. Here, the first auxiliary electrode 672 and the second auxiliary electrode 674 can be removed through a wet etching process.

In this case, in the area where the edge of the second photoresist pattern 692 is disposed on the second passivation layer 617, the first and second auxiliary electrodes 672 and 674 under the second passivation layer 617 can be over-etched, thereby forming the undercut structure where the bottom surface of the second passivation layer 617 is exposed. On the other hand, in the area where the edge of the second photoresist pattern 692 is disposed on the second auxiliary electrode 674, even though the first and second auxiliary electrodes 672 and 674 under the second photoresist pattern 692 is over-etched, the edge of the opening 67a can be disposed in the second contact hole 617a, so that the undercut structure may not be formed.

Next, in FIG. 20J, the second photoresist pattern 692 of FIG. 20I can be stripped and removed.

Then, the third auxiliary electrode 676 can be formed on the overcoat layer 619 by depositing a conductive material and patterning it through a photolithography process. The third auxiliary electrode 676 can overlap the first, second, and third contact holes 615a, 617a, and 619a and can be cut off by the undercut structure.

The third auxiliary electrode 676 can be in contact with the top and side surfaces of the overcoat layer 676, be in contact with the top and side surfaces of the second passivation layer 617 exposed through the third contact hole 619a, be in contact with the top surface of the second auxiliary electrode 674 exposed through the second contact hole 617a, and be in contact with the side surfaces of the first and second auxiliary electrodes 672 and 674 and the top surface of the gate insulation layer 613 exposed through the opening 672a.

Here, the portion of the third auxiliary electrode 676 on the second passivation layer 617 and the overcoat layer 619 can be separated from the portion on the first and second auxiliary electrodes 672 and 674 and the gate insulation layer 613.

Next, in FIG. 20K, the light-emitting layer 644 and the second electrode 646 can be sequentially formed on the third auxiliary electrode 676. The light-emitting layer 644 and the second electrode 646 can be separated by the undercut structure of the second passivation layer 617, and the separated portions of the light-emitting layer 644 and the second electrode 646 can be in contact with the inclined surface of the third auxiliary electrode 676 under the undercut structure.

As such, in the method of manufacturing the electroluminescent display device according to the sixth embodiment of the present disclosure, after the second contact hole 617a of the second passivation layer 617 is formed, the opening 672a can be formed in the first and second auxiliary electrodes 672 and 674. The undercut structure can be provided in the second passivation layer 617 corresponding to the at least one side of the opening 672a, and the third auxiliary electrode 676 can be formed to cover the opening 672a and the undercut structure. Accordingly, the light-emitting layer 644 and the second electrode 646 can be separated by the undercut structure, and the separated second electrode 646 can be configured to be in contact with the inclined surface of the third auxiliary electrode 676, thereby improving the contact properties between the second electrode 646 and the first, second, and third auxiliary electrodes 672, 674, and 676.

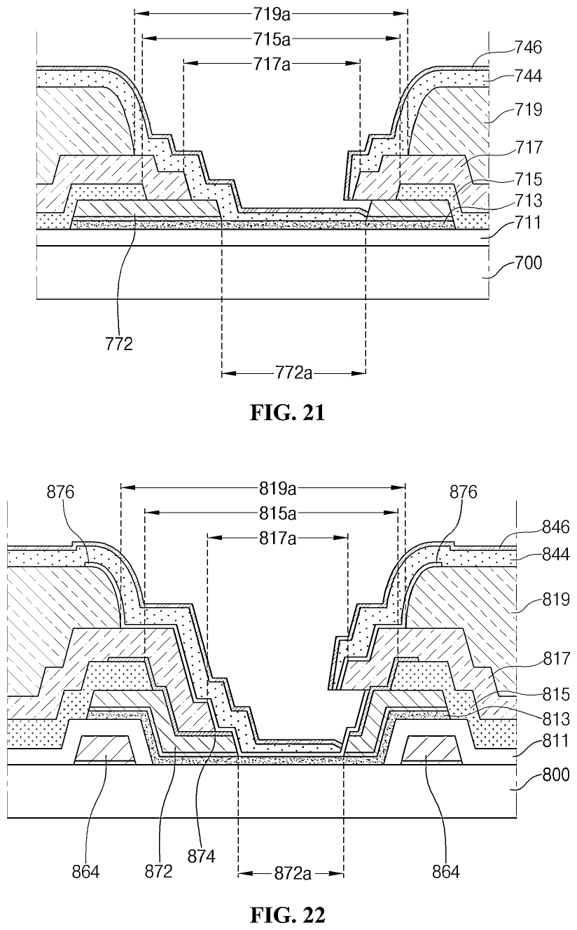

FIG. 21 is a schematic cross-sectional view of a contact area of an electroluminescent display device according to a seventh embodiment of the present disclosure. The electroluminescent display device according to the seventh embodiment of the present disclosure has substantially the same configuration as that of the sixth embodiment, except for the second third auxiliary electrodes. The same parts as those of the sixth embodiment are designated by the same or similar reference signs, and explanation for the same parts may be shortened or omitted.

As shown in FIG. 21, in the electroluminescent display device according to the seventh embodiment of the present disclosure, an opening 772a can be provided in the first auxiliary electrode 772, so that the first auxiliary electrode 772 can have the inclined surface, and the second passivation layer 717, which is an insulation layer on the first auxiliary electrode 772, can have the undercut structure.

Specifically, the buffer layer 711 can be provided on the substrate 700. The gate insulation layer 713 and the first auxiliary electrode 772 can be sequentially provided on the buffer layer 711.

The first auxiliary electrode 772 can have the opening 772a, and the gate insulation layer 713 can be exposed through the opening 772a. The first auxiliary electrode 772 can have the inclined surface, that is, the inclined side surface due to the opening 772a.

The first passivation layer 715 can be provided on the first auxiliary electrode 772. The first passivation layer 715 can have the first contact hole 715a exposing the top surface of the first auxiliary electrode 772. The opening 772a can be disposed in the first contact hole 715a.

The second passivation layer 717 can be provided on the first passivation layer 715. The second passivation layer 717 can have the second contact hole 717a exposing the first auxiliary electrode 772. The second contact hole 717a can also expose the gate insulation layer 713. The second contact hole 717a can be disposed in the first contact hole 715a.

The second contact hole 717a can partially overlap the opening 772a. In the area where an edge of the opening 772a is disposed under the second passivation layer 717, that is, in the area where an edge of the second contact hole 717a is disposed in the opening 772a, an undercut structure in which the bottom surface of the second passivation layer 717 is exposed can be provided. The inclined side surface of the first auxiliary electrode 772 can be substantially exposed under the undercut structure.

The overcoat layer 719 can be provided on the second passivation layer 717. The overcoat layer 719 can have the third contact hole 719a exposing the second passivation layer 717. The second contact hole 717a and the opening 772a can be disposed in the third contact hole 719a.

The light-emitting layer 744 and the second electrode 746 can be sequentially provided on the overcoat layer 719. The light-emitting layer 744 and the second electrode 746 can be cut off by the undercut structure. Accordingly, the portions of the light-emitting layer 744 and the second electrode 746 over the second passivation layer 717 corresponding to the undercut structure can be separated from the portions of the light-emitting layer 744 and the second electrode 746 over the gate insulation layer 713 in the opening 772a, respectively. The separated portions of the light-emitting layer 744 and the second electrode 746 can be in contact with the inclined side surface of the first auxiliary electrode 772 under the undercut structure.

On the other hand, the portions of the light-emitting layer 744 and the second electrode 746 over the second passivation layer 717 that does not correspond to the undercut structure can be connected to the portions of the light-emitting layer 744 and the second electrode 746 over the gate insulation layer 713 in the opening 772a, respectively, without separation.

Here, the total thickness of the light-emitting layer 744 and the second electrode 746 can be smaller than the thickness of the first auxiliary electrodes 772.

As such, in the electroluminescent display device according to the seventh embodiment of the present disclosure, the structure such as the opening 772a can be provided in the first auxiliary electrode 772, so that the first auxiliary electrode 772 can have the inclined surface, that is, the inclined side surface due to the opening 772a, and the second passivation layer 717 over the first auxiliary electrode 772 can be configured to have the undercut structure. Accordingly, each of the light-emitting layer 744 and the second electrode 746 over the second passivation layer 717 can be separated by the undercut structure, and the separated second electrode 746 can be in direct contact with the inclined side surface of the first auxiliary electrode 772 under the undercut structure, thereby improving the contact properties between the second electrode 746 and the first auxiliary electrode 772.

FIG. 22 is a schematic cross-sectional view of a contact area of an electroluminescent display device according to an eighth embodiment of the present disclosure. The electroluminescent display device according to the eighth embodiment of the present disclosure has substantially the same configuration as that of the sixth embodiment, except for the dummy pattern. The same parts as those of the sixth embodiment are designated by the same or similar reference signs, and explanation for the same parts may be shortened or omitted.

As shown in FIG. 22, in the electroluminescent display device according to the eighth embodiment of the present disclosure, by providing a dummy pattern 864 under the first and second auxiliary electrodes 872 and 874, the first and second auxiliary electrodes 872 and 874 can have the inclined step surfaces due to the step difference of the dummy pattern 864. An opening 872a can be provided in the first and second auxiliary electrodes 872 and 874, so that the first and second auxiliary electrodes 872 and 874 can have the inclined side surfaces due to the opening 872a. The second passivation layer 817, which is an insulation layer on the first and second auxiliary electrodes 872 and 874, can have the undercut structure.

Specifically, at least one dummy pattern 864 can be provided on the substrate 800. For example, a couple of dummy patterns 864 can be provided to be spaced apart from each other.

The buffer layer 811 can be provided on the dummy pattern 864. The buffer layer 811 can have the step difference due to the dummy pattern 864.

The gate insulation layer 813 and the first auxiliary electrode 872 can be sequentially provided on the buffer layer 811. The gate insulation layer 813 and the first auxiliary electrode 872 can overlap the dummy pattern 864 and have the step differences due to the dummy pattern 864. The first auxiliary electrode 872 can have the inclined surface, that is, the inclined step surface due to the step difference corresponding to the dummy pattern 864, and the top surface of the first auxiliary electrode 872 can also have the inclined step surface.

The first auxiliary electrode 872 can have the opening 872a, and the gate insulation layer 813 can be exposed through the opening 872a. The first auxiliary electrode 872 can have the inclined surface, that is, the inclined side surface due to the opening 872a.

The first passivation layer 815 can be provided on the first auxiliary electrode 872. The first passivation layer 815 can have the first contact hole 815a exposing the top surface of the first auxiliary electrode 872. The first contact hole 815a can have the larger area than the opening 872a, and the opening 872a can be disposed in the first contact hole 815a.

The second auxiliary electrode 874 can be provided on the first passivation layer 815. The second auxiliary electrode 874 can be in contact with the first auxiliary electrode 872 exposed through the first contact hole 815a. The opening 872a can extend in the second auxiliary electrode 874, and the second auxiliary electrode 874 can have the inclined surface, that is, the inclined side surface due to the opening 872a.

The second passivation layer 817 can be provided on the second auxiliary electrode 874. The second passivation layer 817 can have the second contact hole 817a exposing the second auxiliary electrode 874. The second contact hole 817a can have the smaller area than the first contact hole 815a and be disposed in the first contact hole 815a.

The second contact hole 817a can partially overlap the opening 872a. In the area where an edge of the opening 872a is disposed under the second passivation layer 817, that is, in the area where an edge of the second contact hole 817a is disposed in the opening 872a, an undercut structure in which the bottom surface of the second passivation layer 817 is exposed can be provided. The inclined side surface and the inclined step surface of the first and second auxiliary electrode 872 and 874 can be substantially exposed under the undercut structure.

On the other hand, in the area where the edge of the opening 872a is disposed in the second contact hole 817a, the undercut structure may not be provided, and the top and side surfaces of the second auxiliary electrode 874 and the side surface of the first auxiliary electrode 872 can be exposed through the second contact hole 817a. That is, the undercut structure may not be provided in the area where the edge of the second contact hole 817a is not disposed in the opening 872a and is disposed over the first and second auxiliary electrodes 872 and 874.

The overcoat layer 819 can be provided on the second passivation layer 817. The overcoat layer 819 can a substantially flat top surface and have the third contact hole 819a exposing the second passivation layer 817 and the second auxiliary electrode 874.

The third contact hole 819a can have a larger area than the first contact hole 815a, the second contact hole 817a, and the opening 872a, and the first contact hole 815a, the second contact hole 817a, and the opening 872a can be disposed in the third contact hole 819a. However, embodiments of the present disclosure are not limited thereto. In other embodiments, the third contact hole 819a can have a smaller area than the first contact hole 815a and be disposed in the first contact hole 515a.

The third auxiliary electrode 876 can be provided on the overcoat layer 819. The third auxiliary electrode 876 can have substantially the same area as the second auxiliary electrode 874. The third auxiliary electrode 876 can be in contact with the top and side surfaces of the overcoat layer 819 and be in contact with the top and side surfaces of the second passivation layer 817 exposed through the third contact hole 819a.

In addition, the third auxiliary electrode 876 can be in contact with the top surface of the second auxiliary electrode 874 exposed through the second contact hole 817a. The third auxiliary electrode 876 can also be provided in the opening 872a and be in contact with the top surface of the gate insulation layer 813 and the inclined side surfaces and the inclined step surfaces of the first and second auxiliary electrodes 872 and 874 exposed through the opening 872a. Accordingly, the third auxiliary electrode 876 can have the inclined surface corresponding to the inclined side surfaces and the inclined step surfaces of the first and second auxiliary electrodes 872 and 874.

The light-emitting layer 844 and the second electrode 846 can be sequentially provided on the third auxiliary electrode 876 and the overcoat layer 819.

The light-emitting layer 844 and the second electrode 846 can be cut off by the undercut structure. Accordingly, the portions of the light-emitting layer 844 and the second electrode 846 over the second passivation layer 817 corresponding to the undercut structure can be separated from the portions of the light-emitting layer 844 and the second electrode 846 over the gate insulation layer 813 in the opening 872a, respectively. The separated portions of the light-emitting layer 844 and the second electrode 846 can be in contact with the inclined surface of the third auxiliary electrode 876 under the undercut structure.

On the other hand, the portions of the light-emitting layer 844 and the second electrode 846 over the second passivation layer 817 that does not correspond to the undercut structure can be connected to the portions of the light-emitting layer 844 and the second electrode 846 over the gate insulation layer 813 in the opening 872a, respectively, without separation.

As such, in the electroluminescent display device according to the eighth embodiment of the present disclosure, the structure such as the dummy pattern 864 can be provided under the first and second auxiliary electrodes 872 and 874, and the structure such as the opening 872a can be provided in the first and second auxiliary electrodes 872 and 874, so that the first and second auxiliary electrodes 872 and 874 can have the inclined surfaces, that is, the inclined step surfaces and the inclined side surfaces due to the dummy pattern 864 and the opening 872a. The third auxiliary electrode 876 covering the inclined step surfaces and the inclined side surfaces can be configured to have the inclined surface, and the second passivation layer 817 over the first and second auxiliary electrodes 872 and 874 can be configured to have the undercut structure.

Accordingly, each of the light-emitting layer 844 and the second electrode 846 over the second passivation layer 817 can be separated by the undercut structure, and the separated second electrode 846 can be in direct contact with the inclined surface of the third auxiliary electrode 876 under the undercut structure, thereby improving the contact properties between the second electrode 846 and the first, second, and third auxiliary electrodes 872, 874, and 876.

By increasing the length of the inclined surfaces of the first and second auxiliary electrodes 872 and 874, the electroluminescent display device according to the eighth embodiment of the present disclosure can be implemented without restrictions on the relationship of the total thickness of the light-emitting layer 644 and the second electrode 979 and the total thickness of the first and second auxiliary electrodes 672 and 674 compared with the sixth embodiment.

In the electroluminescent display device of the present disclosure, by connecting the second electrode of the light-emitting diode to the power line through the auxiliary electrode, the resistance of the second electrode can be reduced, and the luminance of the electroluminescent display device can be uniform.

In addition, the auxiliary electrode can be configured to have the inclined surface due to at least one structure, and the second electrode separated by the undercut structure can be configured to be in contact with the inclined surface of the auxiliary electrode, so that the contact property between the second electrode and the auxiliary electrode can be increased.

Accordingly, the luminance of the electroluminescent display device can be improved, and the improved luminance can reduce power consumption, thereby achieving the low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. An electroluminescent display device, comprising:
a substrate including an emission area and a contact area;
a power line over the substrate;
a light-emitting diode in the emission area, the light-emitting diode including a first electrode, a light-emitting layer on the first electrode, and a second electrode on the light-emitting layer;
at least one structure in the contact area;
an auxiliary electrode in the contact area and connected to the power line and the second electrode, the auxiliary electrode having an inclined surface over the at least one structure; and
an insulation layer between the auxiliary electrode and the light-emitting diode, the insulation layer having a contact hole exposing the auxiliary electrode,
wherein a portion of the insulation layer extends past the inclined surface of the auxiliary electrode and an undercut structure is between the inclined surface of the auxiliary electrode and a bottom surface of the portion of the insulation layer that is exposed on at least one side of the contact hole, and
wherein the light-emitting layer and the second electrode are respectively disconnected from another light-emitting layer and another second electrode by the undercut structure such that an end of the light-emitting layer and an end of the second electrode are in contact with the inclined surface of the auxiliary electrode at a location that is under the undercut structure.

2. The electroluminescent display device of claim 1, wherein the at least one structure is a dummy pattern between the substrate and the auxiliary electrode.

3. The electroluminescent display device of claim 2, wherein the dummy pattern includes a same material and is on a same layer as the power line.

4. The electroluminescent display device of claim 1, further comprising:
an island pattern in the contact hole, the island pattern including a same material as the insulation layer,
wherein the island pattern includes a lower pattern and an upper pattern on the lower pattern that extends past an end of the lower pattern, and an undercut structure is between a bottom surface of a portion of the upper pattern and the lower pattern.

5. The electroluminescent display device of claim 4, further comprising:
an interlayer insulation layer having a first contact hole; and
a first island pattern in the first contact hole between the substrate and the insulation layer,
wherein the auxiliary electrode includes a first auxiliary electrode and a second auxiliary electrode,
wherein the interlayer insulation layer and the first island pattern are between the first auxiliary electrode and the second auxiliary electrode, and
wherein the second auxiliary electrode is in contact with the first auxiliary electrode through the first contact hole and has an inclined surface that is over the first island pattern.

6. The electroluminescent display device of claim 5, wherein the contact hole is in the first contact hole, and the island pattern is over the first island pattern.

7. The electroluminescent display device of claim 1, further comprising:
an interlayer insulation layer having a first contact hole between the substrate and the insulation layer,
wherein the auxiliary electrode includes a first auxiliary electrode and a second auxiliary electrode,
wherein the interlayer insulation layer is between the first auxiliary electrode and the second auxiliary electrode, and the second auxiliary electrode is in contact with the first auxiliary electrode through the first contact hole and has an inclined surface in the first contact hole.

8. The electroluminescent display device of claim 7, wherein the contact hole is in the first contact hole.

9. The electroluminescent display device of claim 1, further comprising:
a buffer layer having an opening between the substrate and the auxiliary electrode and the opening overlapping the auxiliary electrode,
wherein the auxiliary electrode has an inclined surface in the opening.

10. The electroluminescent display device of claim 9, wherein the contact hole is in the opening.

11. The electroluminescent display device of claim 9, wherein the auxiliary electrode is in contact with the substrate through the opening.

12. The electroluminescent display device of claim 1, wherein the auxiliary electrode includes an opening and has an inclined surface in the opening.

13. The electroluminescent display device of claim 12, wherein the contact hole partially overlaps the opening, and the undercut structure is in an area where an edge of the contact hole is in the opening.

14. The electroluminescent display device of claim 12, further comprising:
a gate insulation layer between the substrate and the auxiliary electrode,
wherein the light-emitting layer is in contact with the gate insulation layer through the opening.

15. The electroluminescent display device of claim 12, wherein the auxiliary electrode includes a first auxiliary electrode, a second auxiliary electrode, and a third auxiliary electrode,
wherein the insulation layer is between the second auxiliary electrode and the third auxiliary electrode,
wherein the first auxiliary electrode and the second auxiliary electrode include the opening, and the third auxiliary electrode is in the opening and has an inclined surface.

16. The electroluminescent display device of claim 1, further comprising:
an overcoat layer between the insulation layer and the light-emitting diode,
wherein the substrate further includes a transparent area, and the overcoat layer is not in the transparent area such that a portion of the insulation layer is exposed.

17. A display device comprising:
a substrate including an emission area and a contact area;
a power line on the substrate, the power line supplying a voltage;
a transistor on the substrate;
a light emitting element in the emission area and connected to the transistor, the light emitting element including a first electrode, a light-emitting layer on the first electrode, and a second electrode on the light-emitting layer; and
an auxiliary electrode in the contact area that is connected to the power line and the second electrode, the auxiliary electrode having a flat surface and an inclined surface that extends from the flat surface with respect to the substrate,
wherein an end of the second electrode contacts the inclined surface of the auxiliary electrode in the contact area.

18. The display device of claim 17, wherein the end of the second electrode contacts the inclined surface without the second electrode contacting the flat surface of the auxiliary electrode.

19. The display device of claim 17, wherein the light-emitting layer contacts the flat surface and the inclined surface of the auxiliary electrode.

20. The display device of claim 17, further comprising:
an insulation layer between the auxiliary electrode and the light emitting element, the insulation layer having a contact hole exposing a portion of the auxiliary electrode,
wherein a portion of the insulation layer extends past the inclined surface of the auxiliary electrode and an undercut structure is between the inclined surface of the auxiliary electrode and a bottom surface of the portion of the insulation layer that is exposed on at least one side of the contact hole,
wherein the second electrode is disconnected from another second electrode by the undercut structure.

21. The display device of claim 17, further comprising:
a dummy pattern in the contact area, the dummy pattern overlapping the inclined surface of the auxiliary electrode,
wherein the dummy pattern includes a same material and on a same layer as the power line.

22. The display device of claim 17, wherein the auxiliary electrode comprises:
a first auxiliary electrode that is connected to the power line but does not contact the second electrode; and
a second auxiliary electrode that includes the inclined surface that contacts the end of the second electrode and the flat surface that contacts the first auxiliary electrode.
